(19) United States
(12) Patent Application Publication
(10) Pub. No.: US 2024/0312997 A1
(43) Pub. Date: Sep. 19, 2024

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Ta-Chun LIN, Hsinchu (TW); Chun-Sheng Liang, Changhua County (TW); Chih-Hao Chang, Hsin-Chu (TW)

(73) Assignee: Taiwan Semiconductor Manufacturing Company, Ltd., Hsinchu (TW)

(21) Appl. No.: 18/185,394

(22) Filed: Mar. 17, 2023

(51) Int. Cl. H01L 27/092; H01L 21/822; H01L 21/8238; H01L 29/06; H01L 29/08; H01L 29/423; H01L 29/66; H01L 29/775

(52) U.S. Cl. CPC H01L 27/0922; H01L 21/8221; H01L 21/823807; H01L 21/823814; H01L 21/823878; H01L 29/0673; H01L 29/0847; H01L 29/42392; H01L 29/66439; H01L 29/66545; H01L 29/66553; H01L 29/775

(57) ABSTRACT

Provided are a semiconductor device and a method of forming the same. The semiconductor device includes a substrate, a plurality of semiconductor structures, a source/drain (S/D) region, and a gate stack. The substrate includes an active region extending along a first direction. The semiconductor structures are stacked on the active region. The S/D region abuts the plurality of semiconductor structures. The gate stack wraps the semiconductor structures and extends along a second direction different from the first direction. A bottommost semiconductor structure of the semiconductor structures has a width in the second direction greater than a width of a topmost semiconductor structure of the semiconductor structures in the second direction.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, multi-gate devices have been introduced to replace planar transistors. However, there are quite a few challenges to be handled for the multi-gate technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the disclosure.

FIG. 2A is a corresponding fragmentary cross-sectional view of the semiconductor device in FIG. 1 taken along the line A-A in accordance with some embodiments of the disclosure.

FIG. 2B is a corresponding fragmentary cross-sectional view of the semiconductor device in FIG. 1 taken along the line B-B in accordance with some embodiments of the disclosure.

FIG. 2C is a corresponding fragmentary cross-sectional view of the semiconductor device in FIG. 1 taken along the line C-C in accordance with some embodiments of the disclosure.

FIGS. 3, 4, 5, 6A, 7A, 8A, 9A, 10A, 11A, 12A, 13A, 14A, and 15A are corresponding fragmentary cross-sectional views of forming the semiconductor device in FIG. 1 taken along the line A-A in accordance with some embodiments of the disclosure.

FIGS. 6B, 7B, 8B, 9B, 10B, 11B, 12B, 13B, 14B, and 15B are corresponding fragmentary cross-sectional views of forming the semiconductor device in FIG. 1 taken along the line B-B in accordance with some embodiments of the disclosure.

FIGS. 7C, 8C, 9C, 10C, and 11C are corresponding fragmentary cross-sectional views of forming the semiconductor device in FIG. 1 taken along the line C-C in accordance with some embodiments of the disclosure.

FIGS. 16, 17, and 18 are corresponding fragmentary cross-sectional views of forming the semiconductor device in FIG. 1 taken along the line A-A in accordance with some embodiments of the disclosure.

FIG. 19 is a cross-sectional view of the semiconductor device in FIG. 18 in accordance with some alternative embodiments of the disclosure.

FIGS. 20, 21, 22, and 23 are corresponding fragmentary cross-sectional views of forming the semiconductor device in FIG. 1 taken along the line A-A in accordance with some embodiments of the disclosure.

FIGS. 24, 25, and 26 are corresponding fragmentary cross-sectional views of forming the semiconductor device in FIG. 1 taken along the line A-A in accordance with some embodiments of the disclosure.

FIGS. 27, 28, 29, and 30 are corresponding fragmentary cross-sectional views of forming the semiconductor device in FIG. 1 taken along the line A-A in accordance with some embodiments of the disclosure.

FIGS. 31, 32, 33, and 34 are corresponding fragmentary cross-sectional views of forming the semiconductor device in FIG. 1 taken along the line A-A in accordance with some embodiments of the disclosure.

FIGS. 35, 36, 37, and 38 are corresponding fragmentary cross-sectional views of forming the semiconductor device in FIG. 1 taken along the line A-A in accordance with some embodiments of the disclosure.

FIG. 39 is a corresponding fragmentary cross-sectional view of the semiconductor device in FIG. 1 taken along the line A-A in accordance with some embodiments of the disclosure.

FIG. 40 is a cross-sectional view of the semiconductor device in FIG. 39 in accordance with some alternative embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is generally related to semiconductor devices and the fabrication thereof, and more particularly to multi-gate transistors. Multi-gate transistors include those transistors whose gate structures are formed on at least two-sides of a channel region. These multi-gate devices may include a p-type metal-oxide-semiconductor device or an n-type metal-oxide-semiconductor multi-gate device. Specific examples may be presented and referred to herein as FINFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanosheets) associated with a single, contiguous gate structure. However, one of ordinary skill would recognize that the teaching can apply to a single channel (e.g., single nanosheets) or any number of channels. One of ordinary skill may recognize other examples of semiconductor devices that may benefit from aspects of the present disclosure.

Typically, the bottom nanostructure has higher channel resistance than the top nanostructure due to longer channel length, farther S/D junction, and lighter dopants. In accordance with some embodiments, the width of the bottom nanostructure is intentionally enlarged, so that the width of the bottom nanostructure is greater than the width of the top nanostructure. In this case, the effective channel width is increased and the channel resistance is reduced. In addition, the wider bottom nanostructure also improves the epitaxially growth of the S/D regions at the bottom, so as to avoid the voids formed in the S/D regions, thereby enhancing the yield. Further, the narrower top nanostructure is able to avoid the issue of S/D merging due to excessive lateral growth.

Disclosed embodiments relate to a semiconductor device, in particular, a channel structure of a nanosheet FET and its manufacturing method. The embodiments such as those disclosed herein are generally applicable to a surround-gate FET, an omega-gate FET, a gate-all-around (GAA) FET, and/or nanowire transistors, nanosheet transistors, nano-forksheet transistors, complementary FET or any suitable device having stacked nano-structures on the active region (e.g., oxide diffusion (OD)).

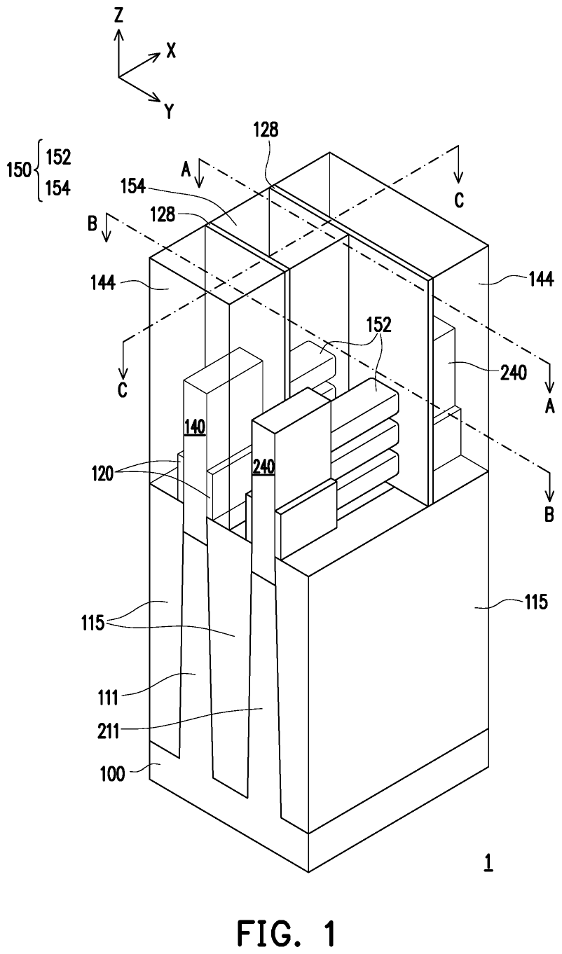

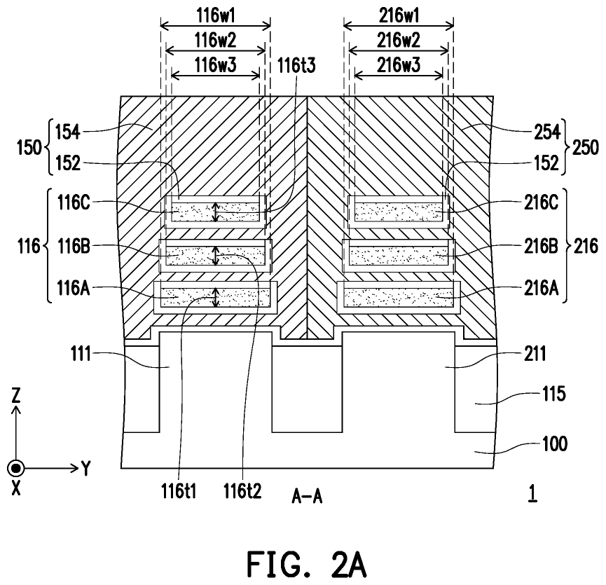

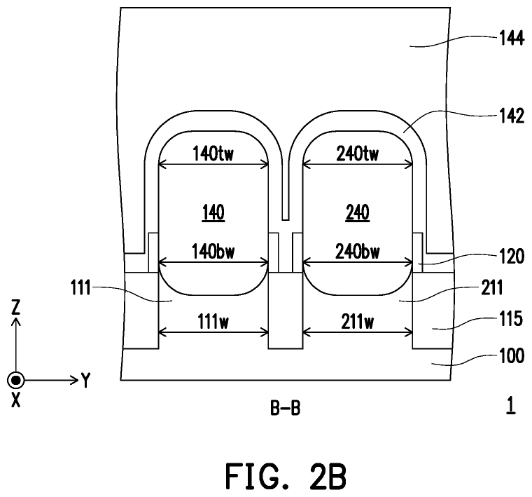

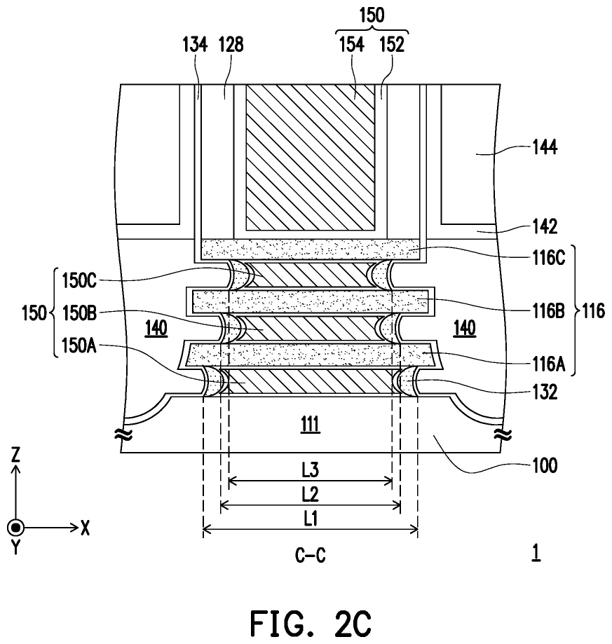

FIG. 1 is a perspective view of a semiconductor device in accordance with some embodiments of the disclosure. FIG. 2A is a corresponding fragmentary cross-sectional view of the semiconductor device in FIG. 1 taken along the line A-A in accordance with some embodiments of the disclosure. FIG. 2B is a corresponding fragmentary cross-sectional view of the semiconductor device in FIG. 1 taken along the line B-B in accordance with some embodiments of the disclosure. FIG. 2C is a corresponding fragmentary cross-sectional view of the semiconductor device in FIG. 1 taken along the line C-C in accordance with some embodiments of the disclosure.

Referring to FIG. 1, FIG. 2A, FIG. 2B, and FIG. 2C, a semiconductor device 1 includes a substrate 100, a plurality of first semiconductor structures 116, a plurality of second semiconductor structures 216, a first source/drain (S/D) region 140, a second S/D region 240, a first gate stack 150, and a second gate stack 250. The substrate 100 includes a first active region 111 and a second active region 211 extending along a X direction (which is also referred to as first direction). The first semiconductor structures 116 may be stacked on the first active region 111. The second semiconductor structures 216 may be stacked on the second active region 211. In some embodiments, the first semiconductor structures 116 and the second semiconductor structures 216 include semiconductor nanosheets, semiconductor wires, or a combination thereof. For example, the first semiconductor structures 116 and the second semiconductor structures 216 may be silicon nanosheets, as shown in FIG. 2A. The first S/D region 140 may abut the first semiconductor structures 116. The second S/D region 240 may abut the second semiconductor structures 216. The first gate stack 150 may wrap the first semiconductor structures 116 and extends along a Y direction (which is also referred to as second direction). The Y direction may be substantially perpendicular to the X direction. The second gate stack 250 may wrap the second semiconductor structures 216 and extends along the Y direction.

It should be noted that, in some embodiments, the length of the gate stack and the length of the first semiconductor structures both change along a Z direction. Specifically, as shown in FIG. 2C, the first semiconductor structures 116 may include semiconductor nanosheets 116A, 116B, and 116C stacked along the Z direction, and the first gate stack 150 may include gate structures 150A, 150B, and 150C along the Z direction. The bottom gate structure 150A has a length L1 in the X direction greater than a length L2 of the middle gate structure 150B in the X direction, and the length L2 of the middle gate structure 150B is greater than a length L3 of the top gate structure 150C in the X direction. That is, the lengths L1, L2, and L3 gradually increase from top to bottom, namely, L1>L2>L3. Therefore, the bottom semiconductor nanosheet 116A may have the longer channel length which results in the greater channel resistance. In addition, the bottom semiconductor nanosheet 116A also has the farther S/D junction due to the shape of the S/D regions 140. Further, the bottom of the S/D regions 140 has the lighter dopant concentration which also results in the greater channel resistance. To solve the said issue, in some embodiments, the width of the bottom semiconductor nanosheet is intentionally enlarged, so that the width of the bottom semiconductor nanosheet is greater than the width of the top semiconductor nanosheet, thereby increasing the effective channel width and reducing the channel resistance. Specifically, as shown in FIG. 2A, the bottom semiconductor nanosheet 116A has a width 116w1 in the Y direction greater than a width 116w2 of the middle semiconductor nanosheet 116B in the Y direction, and the width 116w2 of the middle semiconductor nanosheet 116B is greater than a width 116w3 of the top semiconductor nanosheet 116C in the Y direction. That is, the widths 116w1, 116w2, and 116w3 gradually increase from top to bottom, namely, 116w1>116w2>116w3. In such embodiment, the wider bottom width 116w1 of the bottom semiconductor nanosheet 116A is able to increase the effective channel width, thereby reducing the channel resistance of the bottom semiconductor nanosheet 116A. In some embodiments, a taperness (i.e., 116w1-116w3) between the bottom semiconductor nanosheet 116A and the top semiconductor nanosheet 116C is between 1 nm and 10 nm. In some embodiments, a ratio (i.e., 116w1/116w3) of the bottom semiconductor nanosheet 116A to the top semiconductor nanosheet 116C is between 1.05 and 2.

As shown in FIG. 2A, the semiconductor nanosheets 116A, 116B, and 116C have a thickness 116t1, 116t2, and 116t3 in the Z direction. In some embodiments, the thickness 116t1 of the bottom semiconductor nanosheet 116A is greater than the thickness 116t3 of the top semiconductor nanosheet 116C, so as to improve the current (Ion) of the bottom channel. In some embodiments, a different (i.e., 116t1-116t3) between the bottom semiconductor nanosheet 116A and the top semiconductor nanosheet 116C is between 0.5 nm and 3 nm. In some alternative embodiments, the thickness 116t1 of the bottom semiconductor nanosheet 116A is less than the thickness 116t3 of the top semiconductor nanosheet 116C, so as to improve the short channel effect (SCE) control due to the excessive channel width that results in weaker gate control of the bottom semiconductor nanosheet 116A. In some alternative embodiments, a different (i.e., 116t3-116t1) between the top semiconductor nanosheet 116C and the bottom semiconductor nanosheet 116A is between 0.5 nm and 3 nm.

a different (i.e., 116t1-116t3) between the bottom semiconductor nanosheet 116A and the top semiconductor nanosheet 116C is between 0.5 nm and 3 nm.

Similarly, the second semiconductor structures 216 may include semiconductor nanosheets 216A. 216B, and 216C stacked along the Z direction. The bottom semiconductor nanosheet 216A has a width 216w1 in the Y direction greater than a width 216w2 of the middle semiconductor nanosheet 216B in the Y direction, and the width 216w2 of the middle semiconductor nanosheet 216B is greater than a width 216w3 of the top semiconductor nanosheet 216C in the Y direction. That is, the widths 216w1, 216w2, and 216w3 gradually increase from top to bottom, namely, 216w1>216w2>216w3. In this case, the wider bottom width 216w1 of the bottom semiconductor nanosheet 216A is able to increase the effective channel width, thereby reducing the channel resistance of the bottom semiconductor nanosheet 216A. The taperness of the first semiconductor structures 116 may be different from the taperness of the second semiconductor structures 216 when the semiconductor device 1 is the CMOS device with NMOS and PMOS devices. In some embodiments, a taperness (i.e., 216w1-216w3) between the bottom semiconductor nanosheet 216A and the top semiconductor nanosheet 216C is between 1 nm and 10 nm. In some embodiments, a ratio (i.e., 216w1/216w3) of the bottom semiconductor nanosheet 216A to the top semiconductor nanosheet 216C is between 1.05 and 2.

On the other hand, since the width 116w3 of the top semiconductor nanosheet 116C is less than the width 116w1 of the bottom semiconductor nanosheet 116A, the lateral growth of the top of the S/D regions 140 will be inhibited so that the cross-sectional shape of the S/D regions 140 on the YZ plane is a rectangle, as shown in FIG. 2B. In some embodiments, the top width 140tw of the S/D region 140 in the Y direction is substantially equal to the bottom width 140bw of the S/D region 140 in the Y direction when the width 111w of the first active region 111 in the Y direction is between 5 nm and 150 nm. In this case, a ratio of the top width 140tw to the bottom width 140bw may be between 0.6 and 1.5 when the width 111w of the first active region 111 is between 5 nm and 150 nm. Similarly, the top width 240tw of the S/D region 240 in the Y direction is substantially equal to the bottom width 240bw of the S/D region 240 in the Y direction when the width 211w of the first active region 211 in the Y direction is between 5 nm and 150 nm. When the adjacent S/D regions 140 and 240 are very close to each other, the smaller top widths 140tw and 240tw can prevent the S/D regions 140 and 240 from merging or bridge, thereby enhancing the reliability. However, the embodiments of the present disclosure are not limited thereto, in some alternative embodiments, the top width 140tw/240tw of the S/D region 140/240 is greater than or less than the bottom width 140bw/240bw of the S/D region 140/240.

The semiconductor structures 116/216 with the wider bottom width and the narrower top width may be formed by various manufacturing methods. The following paragraphs will illustrate the detailed steps of the method of forming the semiconductor device 1 shown in FIG. 1.

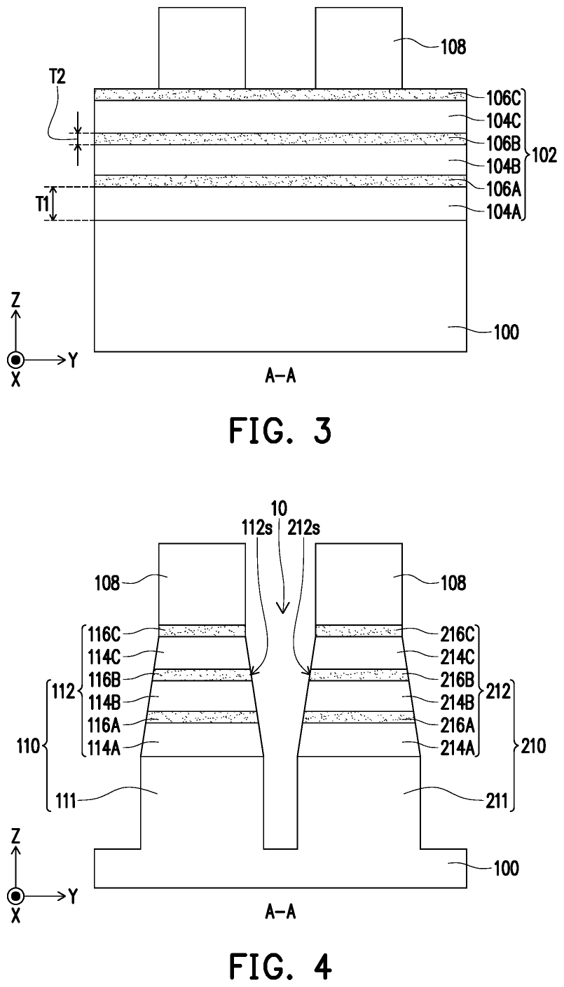

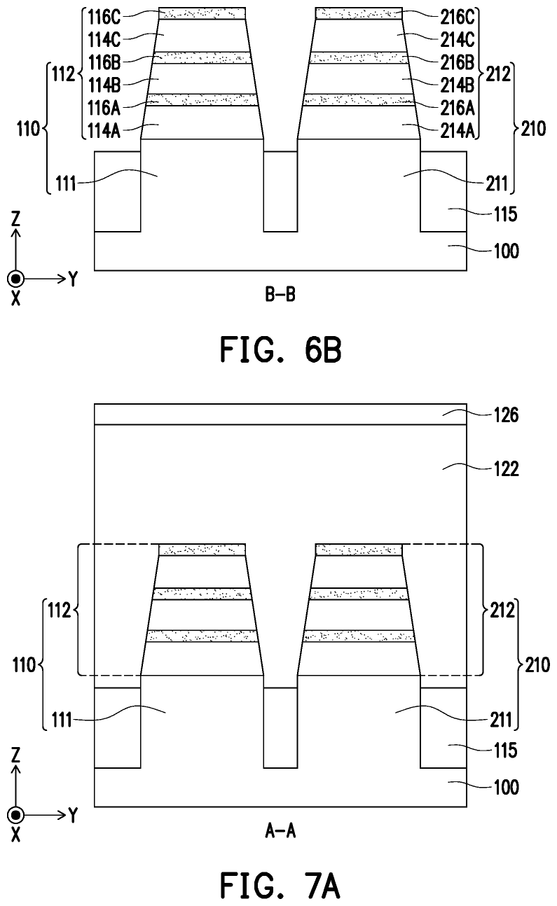

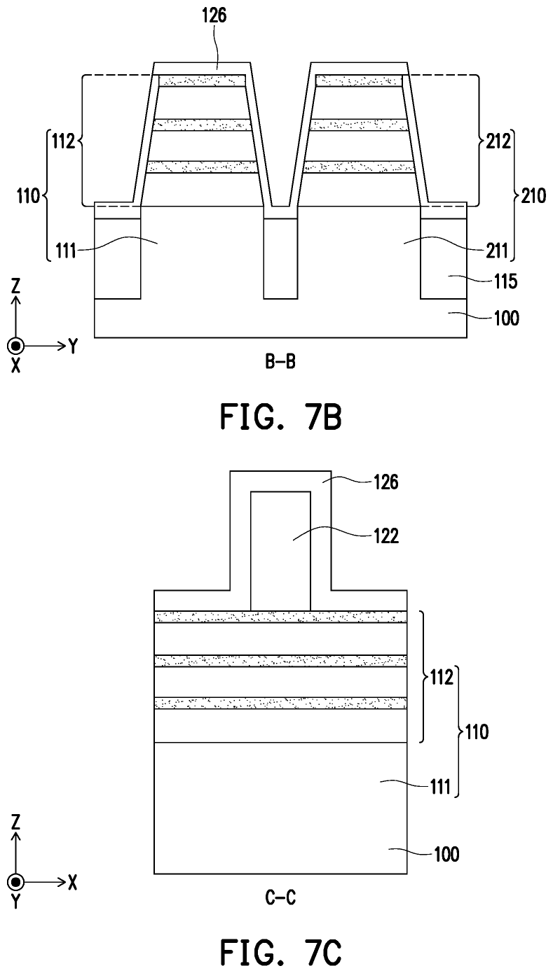

FIGS. 3, 4, 5, 6A, 7A, 8A, 9A, 10A, 11A, 12A, 13A, 14A, and 15A are corresponding fragmentary cross-sectional views of forming the semiconductor device in FIG. 1 taken along the line A-A in accordance with some embodiments of the disclosure. FIGS. 6B. 7B, 8B, 9B, 10B, 11B, 12B, 13B, 14B, and 15B are corresponding fragmentary cross-sectional views of forming the semiconductor device in FIG. 1 taken along the line B-B in accordance with some embodiments of the disclosure. FIGS. 7C, 8C, 9C, 10C, and 11C are corresponding fragmentary cross-sectional views of forming the semiconductor device in FIG. 1 taken along the line C-C in accordance with some embodiments of the disclosure.

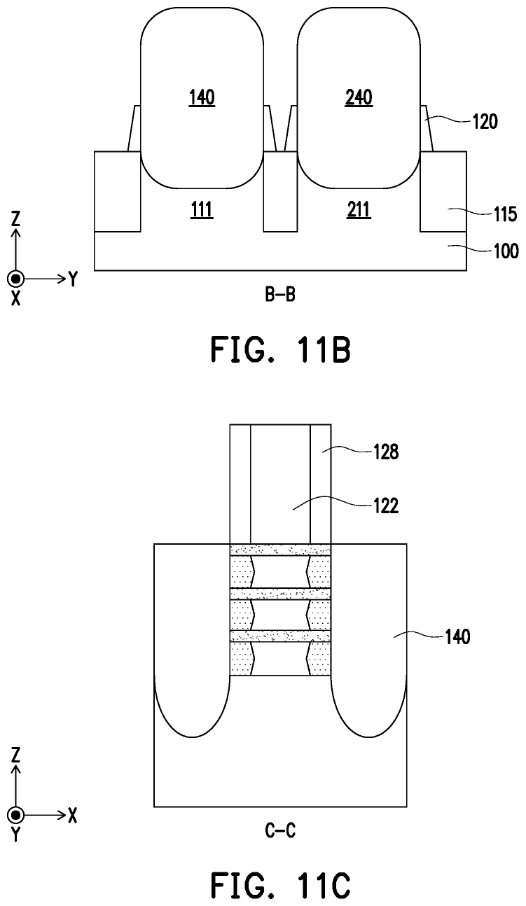

Referring to FIG. 3, a substrate 100 is provided. In some embodiments, the substrate 100 includes a crystalline silicon substrate (e.g., wafer). The substrate 100 may include various doped regions (e.g., p-type well and/or n-type well) depending on design requirements. In some embodiments, the doped regions may be doped with p-type or n-type dopants. For example, the doped regions may be doped with p-type dopants, such as boron or BF2; n-type dopants, such as phosphorus or arsenic; and/or combinations thereof. The doped regions may be configured for an n-type FinFET, or alternatively, configured for a p-type FinFET. In some embodiments, an anti-punch-through (APT) implantation is performed on a top portion of the substrate 100 to form an APT region. The conductivity type of the dopants implanted in the APT region is the same as that of the doped regions (or wells). The APT region may extend under the subsequently formed source/drain (S/D) regions 140/240 (FIG. 11B and FIG. 11C), and are used to reduce the leakage from the S/D regions 140/240 to substrate 100. For clarity, the doped regions and the APT region are not illustrated in FIG. 3 and subsequent drawings. In some alternative embodiments, the substrate 100 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or combinations thereof.

As shown in FIG. 3, a semiconductor stack 102 is formed on the substrate 100. The semiconductor stack 102 may include a plurality of first layers 104A, 104B, 104C (collectively referred to as “first layers 104”) and a plurality of second layers 106A, 106B, 106C (collectively referred to as “second layers 106”) stacked alternately in the Z direction. Although only three first layers 104 and three second layers 106 are illustrated in FIG. 3, the embodiments of the present disclosure are not limited thereto. In other embodiments, the number of the first layers 104 and the second layers 106 are adjusted by the need, such as one first layer, two first layers, four first layers, or more first layers. The number of the second layers corresponds to the number of the first layers.

In some embodiments, the first layers 104 and the second layers 106 include different materials. For example, the first layers 104 are SiGe layers having a germanium percentage in the range between about 15 wt % and 40 wt %, and the second layers 106 are Si layers free from germanium. However, the embodiment of the disclosure is not limited thereto, in other embodiments, the first layers 104 and the second layers 106 have materials with different etching selectivities. In some embodiments, the first layers 104 and the second layers 106 are formed by an epitaxial growth process, such as a molecular beam epitaxy (MBE) process, a metalorganic chemical vapor deposition (MOCVD) process, or the like. In the case, the first layers 104 are epitaxial SiGe layers, and the second layers 106 are epitaxial Si layers. In some alternative embodiments, the first layers 104 and the second layers 106 are formed by a suitable deposition, such as chemical vapor deposition (CVD), atomic layer deposition (ALD), or the like. In the case, the first layers 104 are poly-SiGe layers, and the second layers 106 are poly-Si layers.

In some embodiments, the first layers 104 have the same thickness T1 and the second layers 106 have the same thickness T2. In some embodiments, the thickness T1 may be 5 nm to 20 nm and the second thickness T2 may be 4 nm to 15 nm. Alternatively, the first layers 104A, 104B, and 104C may have different thicknesses, and the second layers 106A, 106B, and 106C may have different thicknesses. In some other embodiments, the first layers 104 and the second layers 106 have the same or different thicknesses.

After forming the semiconductor stack 102, a mask pattern 108 is formed on the semiconductor stack 102. The mask layer 108 may include a single-layered structure, a two-layered structure, or a multi-layered structure. For example, the mask pattern 108 includes a silicon oxide (SiO) layer and a silicon nit1ride (SiN) layer on the SiO layer. In some embodiments, the mask pattern 108 is formed by CVD, ALD, or the like.

Referring to FIG. 3 and FIG. 4, the semiconductor stack 102 and the substrate 100 are then patterned by using the mask pattern 108 as a mask, so as to form a plurality of trenches 10. In this case, a plurality of stacks of first semiconductor strips 112 on the first active region 111 and a plurality of stacks of second semiconductor strips 212 on the second active region 211 are formed between the trenches 10. In some embodiments, the said active region is referred to as oxide diffusion (OD) region. As shown in FIG. 4, the trenches 10 extend into the substrate 100, and have lengthwise directions parallel to each other. In some embodiments, the trench 10 formed between the stacks of first and second semiconductor strips 112 and 212 has a wider top width and a narrower bottom width. Herein, the stacks of first and second semiconductor strips 112 and 212 are referred to as first and second nanosheet stacks 112 and 212. The combination of the first active region 111 and the first nanosheet stack 112 thereon are referred to as a first hybrid fin 110, and the combination of the second active region 211 and the second nanosheet stack 212 thereon are referred to as a second hybrid fin 210. Although only two hybrid fins 110 and 210 are illustrated in FIG. 4, the embodiments of the present disclosure are not limited thereto. In other embodiments, the number of the hybrid fins 110 and 210 may be adjusted by the need, such as one hybrid fin, three hybrid fins, four hybrid fins, or more hybrid fins. In addition, the mask pattern 108 illustrated in FIG. 4 have flat top surfaces. However, the embodiments of the present disclosure are not limited thereto. In other embodiments, the mask pattern 108 may have dome top surfaces due to the high aspect ratio etching.

As shown in FIG. 4, in some embodiments, the first nanosheet stack 112 include a plurality of first nanosheets 114A, 114B, 114C (collectively referred to as “first nanosheets 114”) and a plurality of second nanosheets 116A, 116B, 116C (collectively referred to as “second nanosheets 116”) stacked alternately along a Z direction and extending along the X direction. Similarly, the second nanosheet stack 212 include a plurality of first nanosheets 214A, 214B, 214C (collectively referred to as “first nanosheets 214”) and a plurality of second nanosheets 216A, 216B, 216C (collectively referred to as “second nanosheets 216”) stacked alternately along the Z direction and extending along the X direction.

It should be noted that, in some embodiments, since the first nanosheet stack 112 has a high aspect ratio, when removing portions of the semiconductor stack 102 (FIG. 3) not covered by the mask pattern 108, the removal amount of the upper portion of the semiconductor stack 102 will naturally be greater than that of the lower portion of the semiconductor stack 102. In this case, the result first nanosheet stack 112 may have an inclined sidewall 112s. That is, the bottom nanosheet 116A may have a width in the Y direction greater than a width of the top nanosheet 116C in the Y direction. Similarly, the second nanosheet stack 212 also has an inclined sidewall 212s. That is, the bottom nanosheet 216A may have a width in the Y direction greater than a width of the top nanosheet 216C in the Y direction. Although the sidewalls of the active regions 111 and 211 illustrated in FIG. 4 are vertical sidewalls, the embodiments of the present disclosure are not limited thereto. In other embodiments, the sidewalls of the active regions 111 and 211 are also the inclined sidewalls.

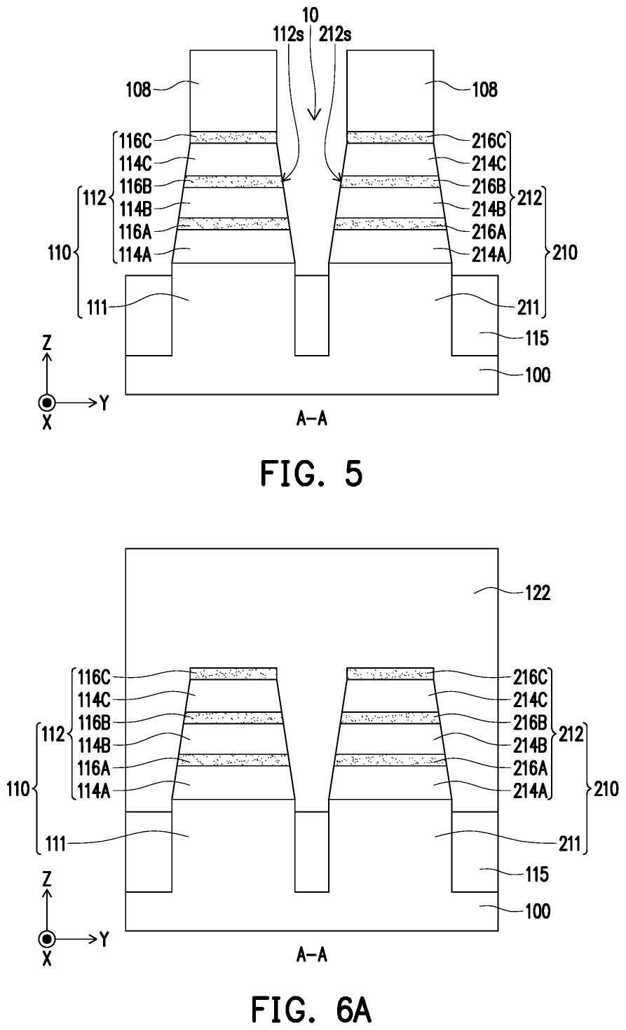

Referring to FIG. 5, an isolation structure 115 is formed to laterally surround the first active region 111 and the second active region 211. In detail, in some embodiments, an insulating material is formed on the substrate 100 to cover the hybrid fins 110 and 210 and to fill up the trenches 10. In addition to the hybrid fins 110 and 210, the insulating material further covers the mask pattern 108. The insulating material may include silicon oxide, silicon nitride, silicon oxynitride, a spin-on dielectric material, or a low-k dielectric material. Herein, the low-k dielectric materials are generally dielectric materials having a dielectric constant lower than 3.9. The insulating material may be formed by flowable chemical vapor deposition (FCVD), high-density-plasma chemical vapor deposition (HDP-CVD), sub-atmospheric CVD (SACVD), or spin on. Then, an etching back process may be performed to remove a portion of the insulating material until the hybrid fins 110 and 210 are exposed. That is, the insulating material is recessed to form the isolation structure 115, wherein the hybrid fins 110 and 210 protrude from top surface of the isolation structure 115. In some embodiments, the nanosheet stacks 112 and 212 are exposed by the isolation structure 115. In some embodiments, the isolation structure 115 may be shallow trench isolation (STI) regions, deep trench isolation (DTI) regions, or the like.

Referring to FIG. 6A and FIG. 6B, after removing the mask pattern 108, a dummy gate 122 is formed over portions of the first nanosheet stacks 112, portions of the second nanosheet stacks 212, and portion of the isolation structure 115. The dummy gate 122 may extend along the Y direction perpendicular to the extending direction of the first and second nanosheet stacks 112 and 212. That is, the dummy gate 122 may be formed across the first and second nanosheet stacks 112 and 212. In some embodiments, the dummy gate 122 includes a silicon-containing material, such as poly-silicon, amorphous silicon, or a combination thereof. The dummy gate 122 may be formed by using a suitable process, such as ALD, CVD, PVD, plating, or combinations thereof. Although the dummy gate 122 illustrated in FIG. 6A is a single-layered structure, the embodiments of the present disclosure are not limited thereto. In other embodiments, the dummy gate 122 may be a multi-layered structure.

Referring to FIG. 7A, FIG. 7B, and FIG. 7C, a spacer material 126 is formed to cover the dummy gate 122 and the exposed portions of the first nanosheet stacks 112 and the second nanosheet stacks 212. In some embodiments, the spacer material 126 is formed of dielectric materials, such as silicon oxide, silicon nitride, carbonized silicon nitride (SiCN), SiCON, or a combination thereof. Although the spacer material 126 illustrated in FIG. 7A, FIG. 7B, and FIG. 7C is a single-layered structure, the embodiments of the present disclosure are not limited thereto. In other embodiments, the spacer material 126 may be a multi-layered structure. For example, the spacer material 126 may include a silicon oxide layer and a silicon nitride layer on the silicon oxide layer. As shown in FIG. 7C, the dummy gate 122 may cover middle portions of the first nanosheet stacks 112, and reveal the opposite end portions not covered.

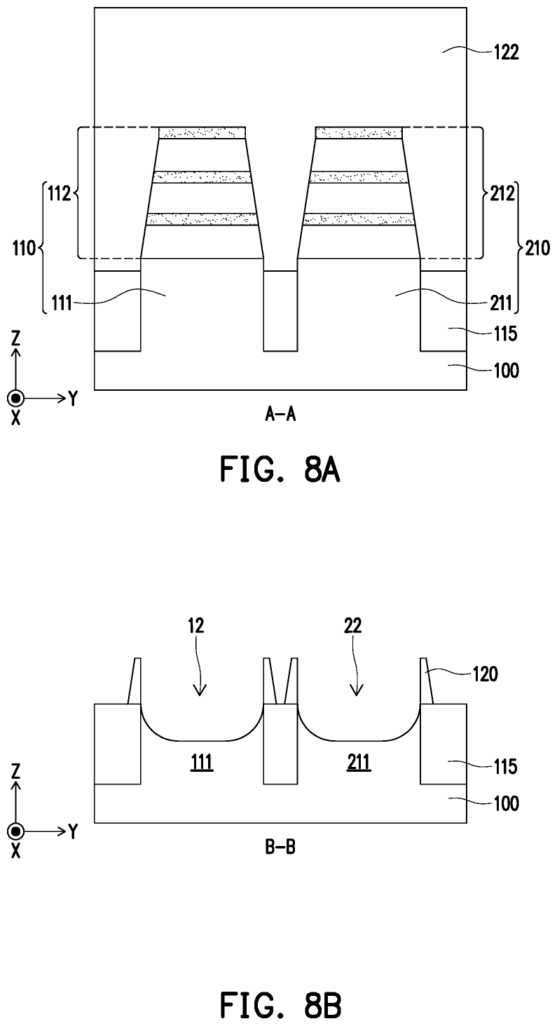

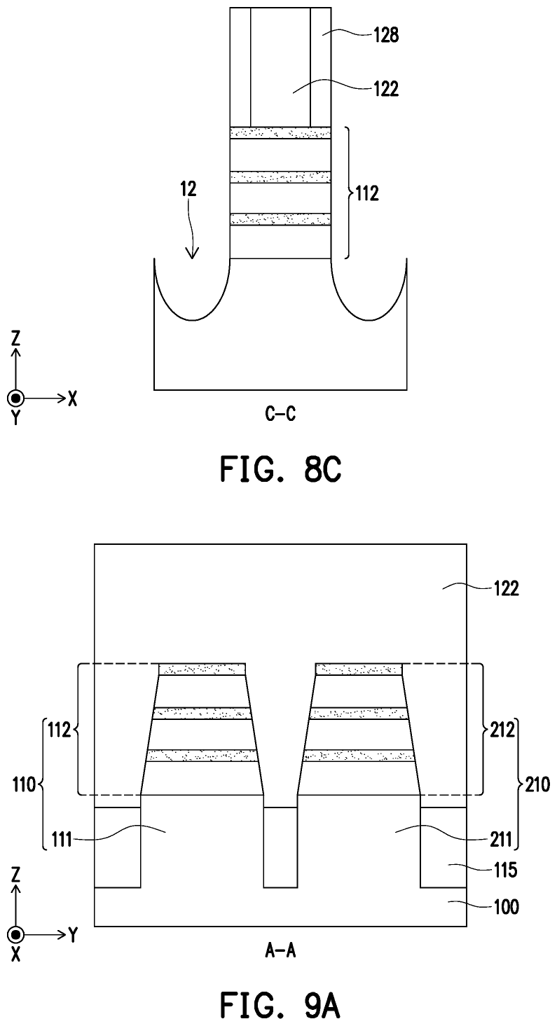

Referring to FIG. 8A, FIG. 8B, and FIG. 8C, an etching process is performed to remove a portion of the spacer material 126, and then remove the end portions of the first nanosheet stacks 112 and the end portions of the second nanosheet stacks 212. Specifically, the end portions of the first nanosheet stacks 112 and the end portions of the second nanosheet stacks 212 are removed and recessed to form recesses 12 and 22. Herein, the recesses 12 and 22 may be referred to as source/drain (S/D) recesses 12 and 22. In some embodiments, the end portions of the first nanosheet stacks 112 and the end portions of the second nanosheet stacks 212 may be removed by an anisotropic etching process, an isotropic etching process, or a combination thereof. In some embodiments, the S/D recesses 12 and 22 further extend into the active regions 111 and 211 and lower than the top surface of the isolation structure 115. In other words, the end portions of the first nanosheet stacks 112 and the end portions of the second nanosheet stacks 212 are entirely removed and portions of the active regions 111 and 211 are further removed. In the case, as shown in FIG. 8B, the bottom surfaces of the S/D recesses 12 and 22 are lower than the top surface of the isolation structure 115. In some embodiments, some portions of the spacer material 126 are removed and other portions of the spacer material 126 may be left standing over and aligned to the edges of isolation structure 115, with the S/D recesses 12 and 22 formed therebetween. Herein, the other portions of the spacer material 126 may be referred to as fin spacers 120. In addition, the remaining portions of the spacer material 126 (FIG. 8C) covered sidewalls of the dummy gate 122 are referred to as gate spacers 128. In some embodiments, the gate spacers 128 and the dummy gate 122 have the same extending direction, namely, the Y direction.

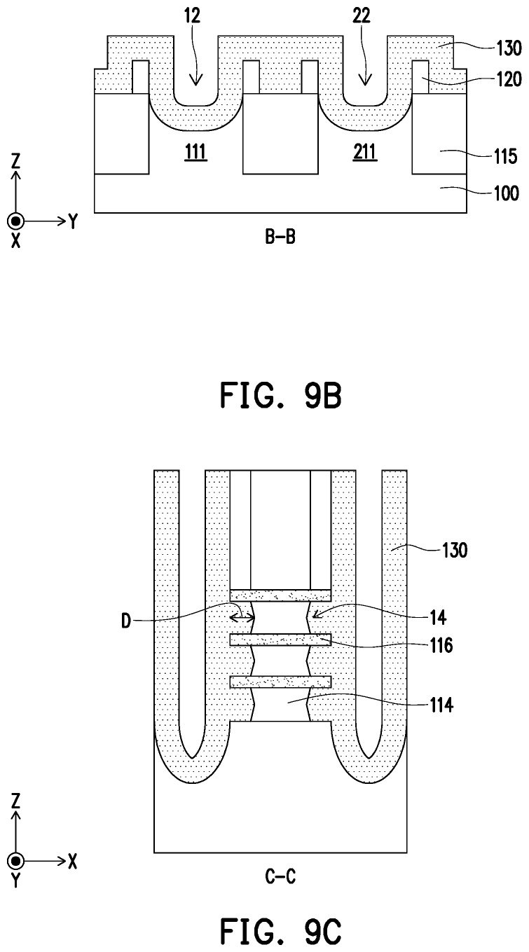

Referring to FIG. 9A, FIG. 9B, and FIG. 9C, after forming the S/D recesses 12 and 22, portions of the first nanosheets 114 and 214 are laterally recessed. For clarity, the following paragraphs are only illustrated by the cross-sectional view of the first nanosheets 114 in FIG. 9C, and the first nanosheets 214 also has the same forming steps and result structure, thus details will not be repeated here. In some embodiments, the portions of the first nanosheets 114 exposed by the S/D recesses 12 are removed, and thus as shown in FIG. 9C, a plurality of cavities 14 are respectively formed between the second nanosheets 116. In some embodiments, the first nanosheets 114 are laterally recessed by a wet etching, a dry etching, or a combination thereof. For example, the first nanosheets 114 may be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, before laterally recessing the portions of the first nanosheets 114, the end portions of the first nanosheets 114 exposed by the recesses 12 may be selectively oxidize, so as to increase the etching selectivity between the first and second nanosheets 114 and 116. In some alternative embodiments, the oxidation process may be performed by exposing to a wet oxidation process, a dry oxidation process, or a combination thereof. The chemical used in the oxidation process may include H₂SO₄ or the like.

In some embodiments, as shown in FIG. 9C, the cavities 14 have the same (lateral) depth D. Herein, the depth D is respectively measured from the sidewall of one second nanosheet 116 to the sidewall of the respective first nanosheet 114. In other words, the sidewalls of the second nanosheets 116 are not aligned with the sidewalls of the first nanosheet 114. However, the embodiments of the present disclosure are not limited thereto, in other embodiments, the cavities 14 have different depths. In this case, the depths D of the cavities 14 may increase from bottom to top.

After forming the cavities 14, an inner spacer material layer 130 is formed on the substrate 100. In some embodiments, the inner spacer material layer 130 conformally covers the S/D recesses 12 and 22, the dummy gate 122, and the gate spacers 128, and further fills in the cavities 14. In some embodiments, the inner spacer material layer 130 includes silicon oxides, silicon nitrides, silicon carbides, silicon carbide nitride, silicon oxide carbide, silicon carbide oxynitride, and/or other suitable dielectric materials, and may be formed by ALD or any other suitable method. In some alternative embodiments, the inner spacer material layer 130 include a low-k dielectric material having a dielectric constant lower than 3.9.

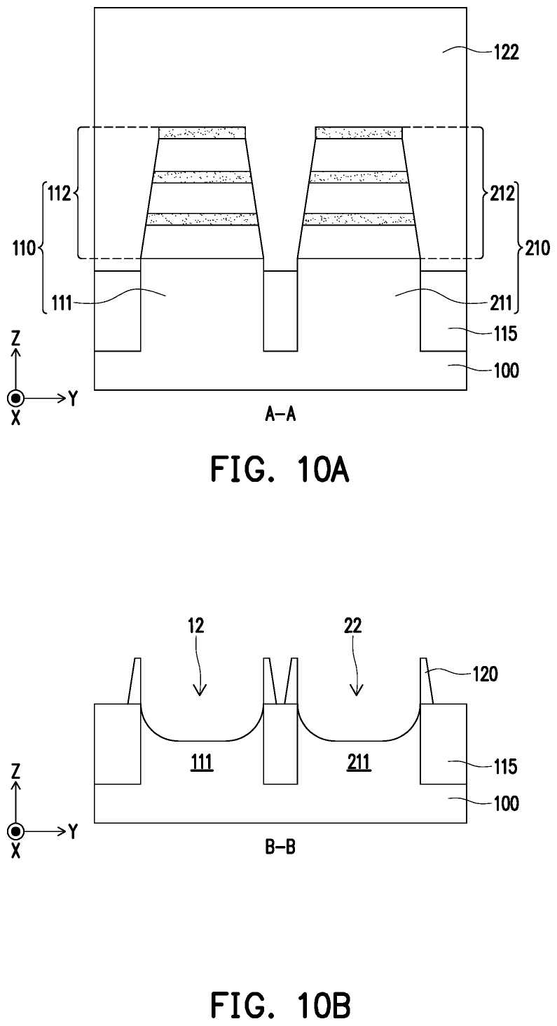

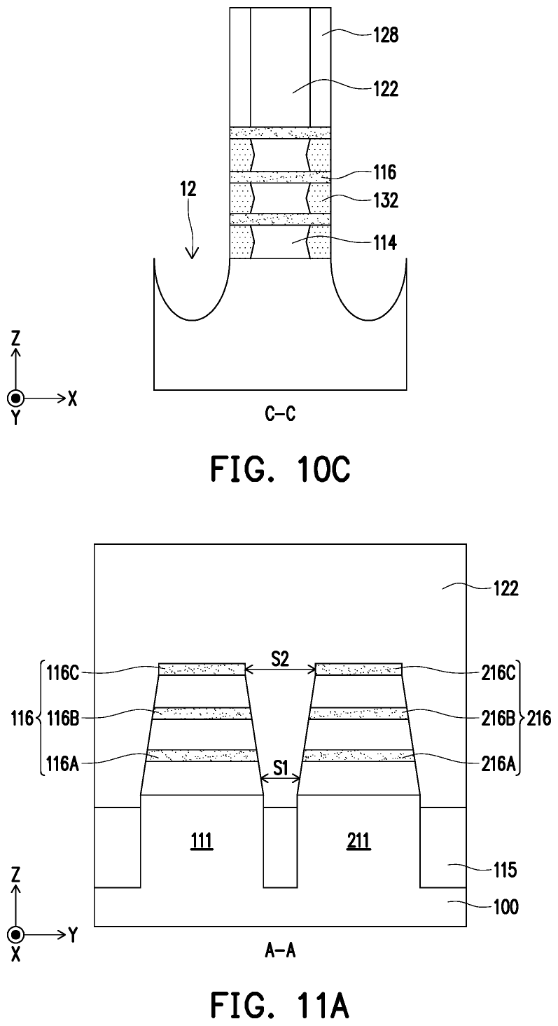

Referring to FIG. 10A, FIG. 10B, and FIG. 10C, a portion of the inner spacer material layer 130 is removed to form a plurality of inner spacers 132 in the cavities 14. In some embodiments, the portion of the inner spacer material layer 130 is removed by a plasma dry etching or any other suitable method. Generally, the plasma dry etching etches a layer in wide and flat areas faster than a layer in concave (e.g., holes, grooves and/or slits) portions. Thus, the inner spacer material layer 130 may remain inside the cavities 14. The remained portions of the inner spacer material layer 130 is referred to as the inner spacers 132. In some embodiments, as shown in FIG. 10C, the inner spacers 132 have the same length. However, the embodiments of the present disclosure are not limited thereto, in other embodiments, the inner spacers 132 have different lengths. In this case, the lengths of the inner spacers 132 may increase from bottom to top.

Referring to FIG. 11A, FIG. 11B, and FIG. 11C, a strained material 140 (or a highly doped low resistance material) are epitaxially grown from the active region 111 and the second nanosheets 116. In some embodiments, the strained material 140 is used to strain or stress the second nanosheets (which may be referred to as channel members) 116 and the active region 111. Herein, the strained material 140 may be referred to as first S/D regions 140. In the case, the strained material 140 includes a source disposed at one side of the dummy gate 122 and a drain disposed at another side of the dummy gate 122. The source covers an end of the active region 111, and the drain covers another end of the active region 111. The S/D regions 140 are abutted and electrically connected to the second nanosheets 116, while the S/D regions 140 are electrically isolated from the first nanosheets 114 by the inner spacers 132.

In some embodiments, a liner layer 134 is optionally formed between the S/D regions 140 and the inner spacers 132, between the S/D regions 140 and the second nanosheets 116, and between the S/D regions 140 and the active region 111. In this case, the S/D regions 140 is derived from the material of the liner layer 134. For example, when the liner layer 134 is polysilicon layer, the strained material 140 may be a silicon-containing material. It should be noted that the liner layer 134 is benefit for forming the S/D regions 140 in the cavities 14. Specifically, the inner spacers 132 made of the dielectric material is not favorable for epitaxially growing the S/D regions, which may form voids between the inner spacers 132 and the S/D regions 140, thereby affecting the strain in the channels and the performance of the device. In other words, the liner layer 134 may provide a good interface for epitaxially growing the S/D regions 140 which is benefit to control the height and shape of the S/D regions 140, thereby reducing void defects and retaining strain in the channels. In addition, a combination of the liner layer 134 and the inner spacers 132 made of the low-k dielectric material may improve the parasitic capacitance, thereby enhancing the performance of the device.

In some other embodiments, the S/D regions 140 include any acceptable material, such as appropriate for p-type FinFETs. For example, if the liner layer 134 is silicon, the S/D regions 140 may include SiGe, SiGeB, Ge, GeSn, or the like. In some alternative embodiments, the S/D regions 140 includes any acceptable material, such as appropriate for n-type FinFETs. For example, if the liner layer 134 is silicon, the S/D regions 140 may include silicon, SiC, SiCP, SiP, or the like. In some embodiments, the S/D regions 140 are formed by MOCVD, MBE, ALD, or the like.

In some embodiments, the S/D regions 140 may be doped with a conductive dopant. For example, the S/D regions 140, such as SiGe, may be epitaxial-grown with a p-type dopant for straining a p-type FinFET. That is, the S/D regions 140 is doped with the p-type dopant to be the source and the drain of the p-type FinFET. The p-type dopant includes boron or BF₂, and the S/D regions 140 may be epitaxial-grown by LPCVD process with in-situ doping. In some alternative embodiments, the S/D regions 140, such as SiC. SiP, a combination of SiC/SiP, or SiCP is epitaxial-grown with an n-type dopant for straining an n-type FinFET. That is, the S/D regions 140 is doped with the n-type dopant to be the source and the drain of the n-type FinFET. The n-type dopant includes arsenic and/or phosphorus, and the S/D regions 140 may be epitaxial-grown by LPCVD process with in-situ doping.

On the other hand, another strained material 240 (or a highly doped low resistance material) are epitaxially grown from the active region 211 and the second nanosheets 216. In some embodiments, the strained material 240 is used to strain or stress the second nanosheets (which may be referred to as channel members) 216 and the active region 211. Herein, the strained material 240 may be referred to as second S/D regions 240. In the case, the strained material 240 includes a source disposed at one side of the dummy gate 122 and a drain disposed at another side of the dummy gate 122. The source covers an end of the active region 211, and the drain covers another end of the active region 211. The S/D regions 240 are abutted and electrically connected to the second nanosheets 216, while the S/D regions 240 are electrically isolated from the first nanosheets 214 by the inner spacers 132.

In the present embodiment, the first S/D regions 140 and the second S/D regions 240 have different materials with different conductive dopants. For example, the first S/D regions 140 may be epitaxial-grown with a p-type dopant for straining a p-type FinFET, while the second S/D regions 240 may be epitaxial-grown with a n-type dopant for straining a n-type FinFET, vice versa. It should be noted that the wider bottom semiconductor nanosheet 116A/216A can improve the epitaxially growth of the S/D regions 140/240 at the bottom, so as to avoid the voids formed in the S/D regions 140/240, thereby enhancing the yield. Further, the narrower top semiconductor nanosheets 116C and 216C is able to avoid the issue of S/D merging due to excessive lateral growth.

In some embodiments, a space S1 between the bottommost semiconductor nanosheet 116A and the bottommost semiconductor nanosheet 216A is less than a space S2 between the topmost semiconductor nanosheet 116C and the topmost semiconductor nanosheets 216C. In this case, the larger space S2 may reserve more room to prevent the S/D regions 140 and 240 from merging when the adjacent S/D regions 140 and 240 are very close to each other. That is, the larger space S2 may increase the process window of epitaxially growing the S/D regions 140 and 240, thereby enhancing the reliability. In some embodiments, a taperness (i.e., S2-S1) between the space S2 and the space S1 is between 1 nm and 10 nm.

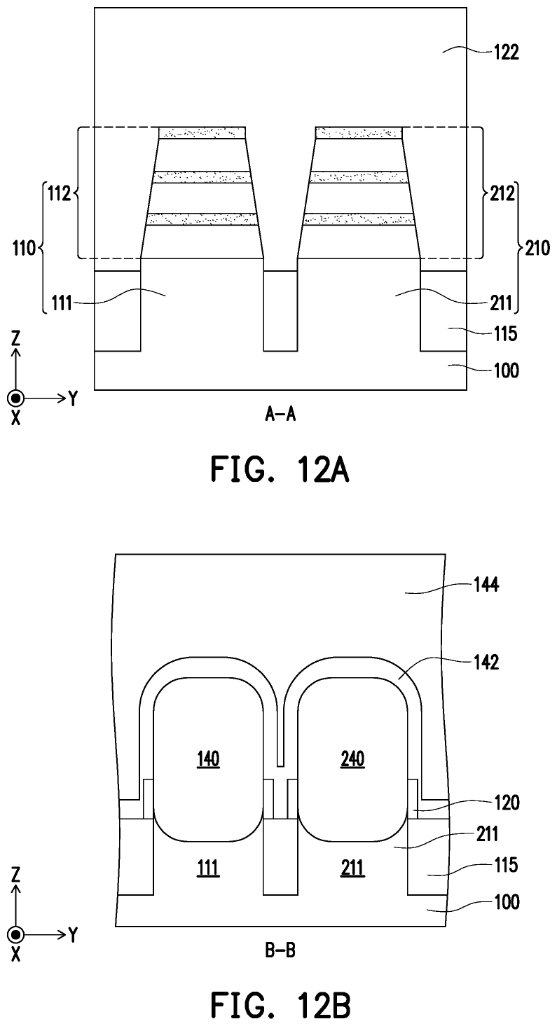

Referring to FIG. 12A and FIG. 12B, a contact etch stop layer (CESL) 142 is formed on the S/D regions 140, 240, and then an interlayer dielectric (ILD) layer 144 is formed on the CESL 142. In some embodiments, the CESL 142 conformally covers the S/D regions 140, 240 and the fin spacers 120. The CESL 142 may include silicon nitride, silicon oxynitride, silicon nitride with oxygen (O) or carbon (C) elements, and/or other materials; and may be formed by CVD, PVD (physical vapor deposition), ALD, or other suitable methods. In some embodiments, the ILD layer 144 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof. In some other embodiments, the ILD layer 144 includes low-k dielectric materials. Examples of low-k dielectric materials include BLACK DIAMOND® (Applied Materials of Santa Clara, Calif.), Xerogel, Acrogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), and/or a combination thereof. In alternative embodiments, the ILD layer 144 include one or more dielectric materials and/or one or more dielectric layers. In some embodiments, the ILD layer 144 is formed to a suitable thickness by FCVD. CVD. HDPCVD, SACVD, spin-on, sputtering, or other suitable methods. For example, an interlayer dielectric material layer (not shown) is initially formed to cover the isolation structure 115, the dummy gate 122, and the gate spacers 128. Subsequently, a thickness of the interlayer dielectric material layer is reduced until the dummy gate 122 is exposed, so as to form the ILD layer 144. In the case, the liner layer 134 on the top surface of the dummy gate 122 is also removed. The process of reducing the thickness of the interlayer dielectric material layer may be achieved by a chemical mechanical polishing (CMP) process, an etching process, or other suitable processes. In the case, the top surface of the ILD layer 144 may be coplanar with the top surface of the dummy gate 122.

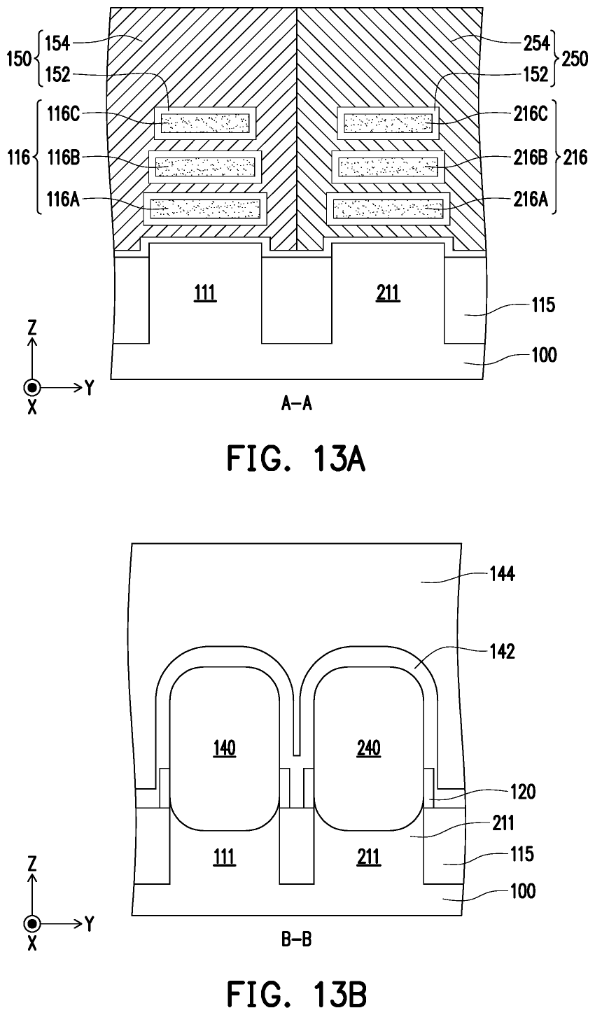

Referring to FIG. 13A and FIG. 13B, a gate replacement process is performed to replace the dummy gate with metal gate. Specifically, the dummy gate 122 is removed to form a gate trench. The ILD layer 144 and the CESL 142 may protect the S/D regions 140 and 240 during removing the dummy gate 122. The dummy gate 122 may be removed by using plasma dry etching and/or wet etching. When the dummy gate electrode is polysilicon and the ILD layer 144 is silicon oxide, a wet etchant such as a TMAH solution may be used to selectively remove the dummy gate electrode. The dummy gate dielectric layer is thereafter removed by using another plasma dry etching and/or wet etching.

Next, an etching process is performed to remove the first nanosheets 114, 214. In the case, the first nanosheets 114, 214 may be completely removed to form a plurality of gaps between the second nanosheets 116, 216. Accordingly, the second nanosheets 116, 216 are separated from each other by the gaps. In addition, the bottommost second nanosheets 116, 216 may also be separated from the active regions 111, 211 by the gaps. As a result, the second nanosheets 116, 216 are suspended. The opposite ends of the suspended second nanosheets 116, 216 are connected to S/D regions 140, 240. Herein, the suspended second nanosheets 116, 216 may be referred to as channel members 116, 216. Herein the etching process may be referred to as nanosheet formation or releasing nanosheet process.

Then, a gate dielectric layer 152 is formed in the gate trench and the gaps. In some embodiments, the gate dielectric layer 152 includes one or more layers of a dielectric material, such as silicon oxide, silicon nitride, or high-k dielectric material, other suitable dielectric material, and/or combinations thereof. Examples of high-k dielectric material include HfO2, HfSiO, HfSiON, HfTaO, HTiO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, the gate dielectric layer 152 includes an interfacial layer (not shown) formed between the channel members and the dielectric material. The gate dielectric layer 152 may be formed by CVD, ALD or any suitable method. In one embodiment, the gate dielectric layer 152 is formed by using a highly conformal deposition process, such as ALD in order to ensure the formation of a gate dielectric layer having a uniform thickness around each channel members.

Afterward, a gate electrode 154 is formed on the gate dielectric layer 152 on the first active region 111 to surround each nanosheet or channel member 116, and another gate electrode 254 is formed on the gate dielectric layer 152 on the second active region 211 to surround each nanosheet or channel member 216. In the case, the gate electrode 154 and the gate dielectric layer 152 constitute a first gate stack 150, and the gate electrode 254 and the gate dielectric layer 152 constitute a second gate stack 250, thereby accomplishing the semiconductor device 1, as shown in FIG. 1.

The gate electrodes 154, 254 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN. TaC. TaSiN, metal alloys, other suitable materials, and/or combinations thereof. The gate electrodes 154, 254 may be formed by CVD, ALD, electro-plating, or other suitable method. In the present embodiment, the gate electrodes 154, 254 have different conductive materials. For example, the gate electrodes 154 may include a first metal for p-type device, while the gate electrodes 254 may include a second metal for n-type device.

In some alternative embodiments, one or more work function adjustment layers (not shown) are interposed between the gate dielectric layer 152 and the gate electrodes 154, 254. The work function adjustment layers are made of a conductive material, such as a single layer of TiN, TaN, TaAlC, TiC. TaC, Co, Al, TiAl, HfTi, TiSi, TaSi or TiAlC, or a multilayer of two or more of these materials. For the n-type device, one or more of TaN, TaAlC, TiN, TIC, Co, TiAl, HfTi, TiSi and TaSi is used as the work function adjustment layer, and for the p-type device, one or more of TiAlC, Al, TiAl, TaN, TaAlC, TiN, TiC and Co is used as the work function adjustment layer. The work function adjustment layer may be formed by ALD, PVD, CVD, e-beam evaporation, or other suitable process. Further, the work function adjustment layer may be formed separately for the n-type device and the p-type device which may use different metal layers.

It should be noted that, in some embodiments, the width of the first and second semiconductor structures both change along the Z direction. Specifically, as shown in FIG. 13A, the first semiconductor structures 116 may include semiconductor nanosheets 116A, 116B, and 116C stacked along the Z direction, and the bottommost semiconductor nanosheets 116A has a width greater than a width of the topmost semiconductor nanosheets 116C. In addition, the second semiconductor structures 216 may include semiconductor nanosheets 216A, 216B, and 216C stacked along the Z direction. The bottommost semiconductor nanosheets 216A has a width greater than a width of the topmost semiconductor nanosheets 216C. In such embodiment, the wider bottom width of the bottommost semiconductor nanosheets 116A and 216A is able to increase the effective channel width, thereby reducing the channel resistance of the bottommost semiconductor nanosheets 116A and 216A.

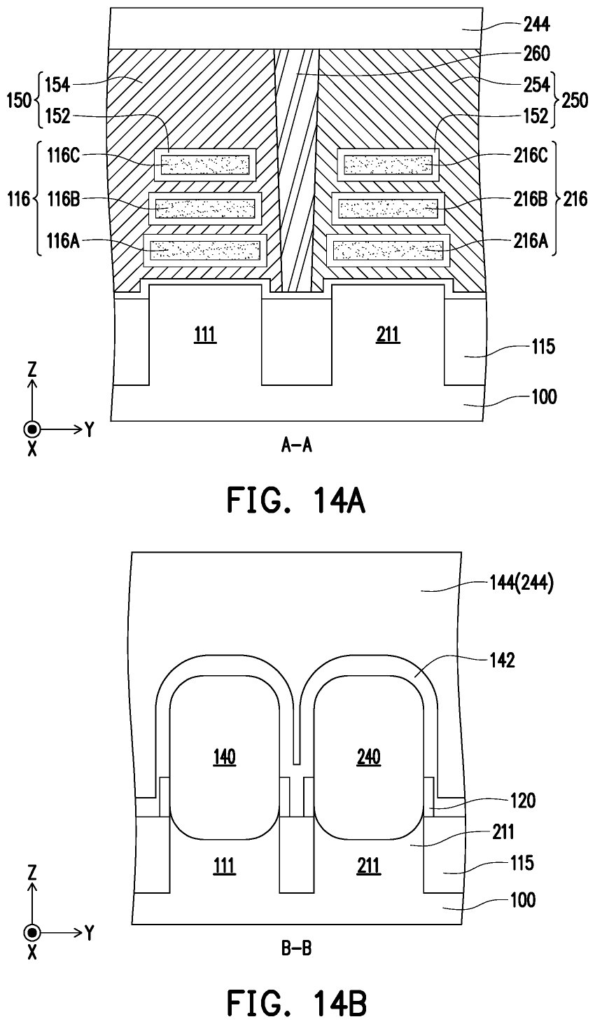

Referring to FIG. 14A and FIG. 14B, a cut metal gate (CMG) 260 is formed on the isolation structure 115 between the first gate stack 150 and the second gate stack 250, so that the first gate stack 150 is electrically isolated from the second gate stack 250 by the CMG 260. In some embodiments, the CMG 260 include a dielectric material such as silicon oxide, silicon nitride, silicon oxynitride, the like, or a combination thereof, and may be formed by CVD, ALD or any suitable method.

After forming the CMG 260, a dielectric layer 244 is formed on the ILD layer 144. Specifically, the dielectric layer 244 may extend from the ILD layer 144 to cover the CMG 260, the first gate stack 150, and the second gate stack 250, as shown in FIG. 14A. In some embodiments, the dielectric layer 244 may have the same dielectric material with the ILD layer 144, such as silicon oxide. In this case, the combination of the dielectric layer 244 and the ILD layer 144 shown in FIG. 14B is illustrated as a single-layered structure.

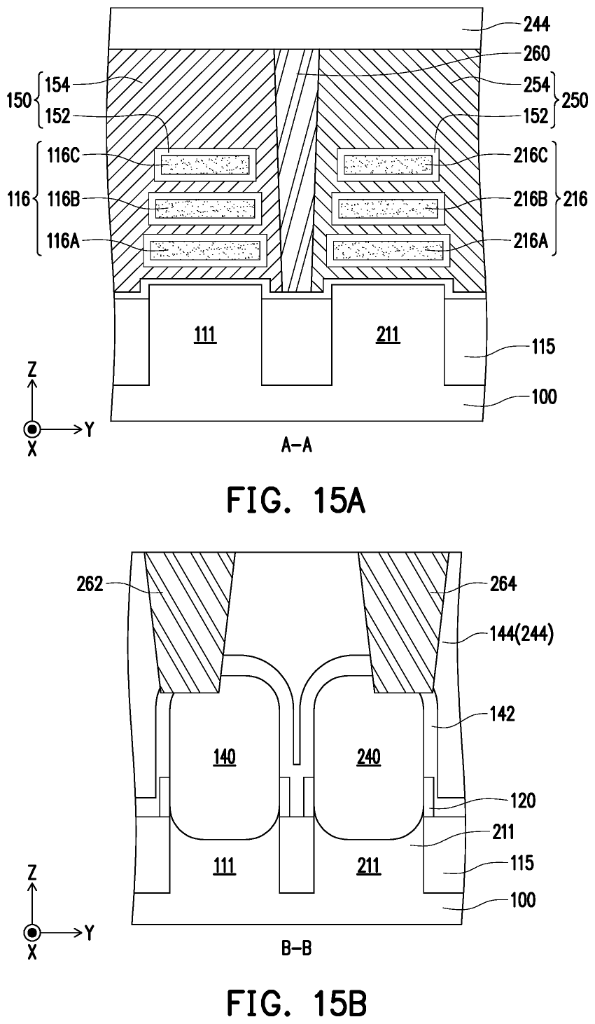

Referring to FIG. 15A and FIG. 15B, metal-to-drain/source (MD) contact structures 262 and 264 are formed in the dielectric layer 244 and the ILD layer 144. Specifically, the MD contact structure 262 may penetrate through the dielectric layer 244, the ILD layer 144, and the CESL 142 to contact the S/D regions 140, while the MD contact structure 264 may penetrate through the dielectric layer 244, the ILD layer 144, and the CESL 142 to contact the S/D regions 240. In some embodiments, the MD contact structures 262 and 264 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The MD contact structures 262 and 264 may be formed by CVD, ALD, electro-plating, or other suitable method.

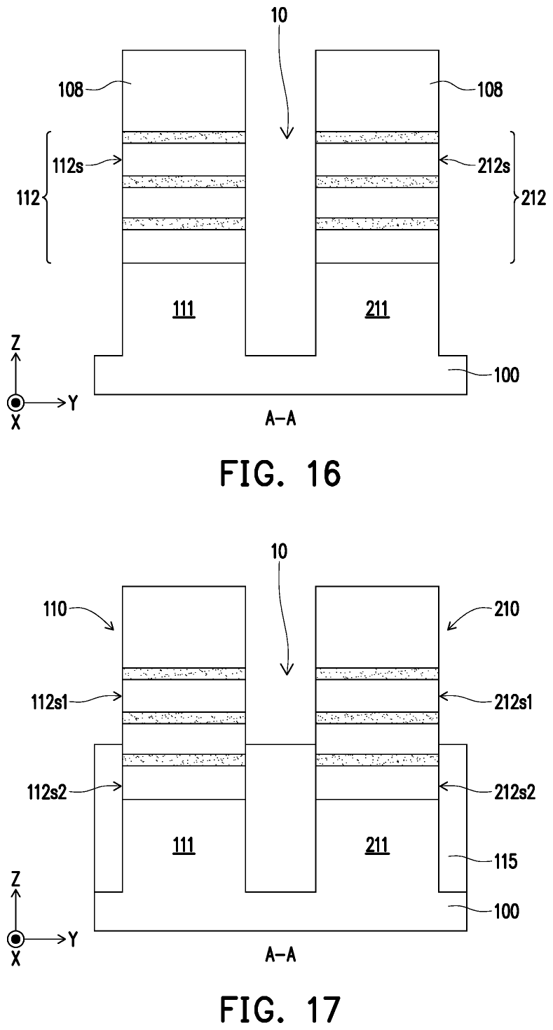

FIGS. 16, 17, and 18 are corresponding fragmentary cross-sectional views of forming the semiconductor device in FIG. 1 taken along the line A-A in accordance with some embodiments of the disclosure.

Referring to FIG. 16, after patterning the semiconductor stack 102 and the substrate 100, the stack of first semiconductor strips 112 on the first active region 111 and the stack of second semiconductor strips 212 on the second active region 211 are formed between the trenches 10. The structure illustrated in FIG. 16 is similar to the structure illustrated in FIG. 4, that is, the structures, materials, and configurations of the structure illustrated in FIG. 16 are similar to those of the structure illustrated in FIG. 4, and thus the details are omitted herein. The main difference therebetween lies in that the stack of first semiconductor strips 112 illustrated in FIG. 16 may have a vertical sidewall 112s substantially perpendicular to the top surface of the substrate 100. Similarly, the stack of second semiconductor strips 212 also has a vertical sidewall 212s substantially perpendicular to the top surface of the substrate 100.

Referring to FIG. 17, an isolation structure 115 is formed to laterally surround bottom portions of the stack of first semiconductor strips 112 and the stack of second semiconductor strips 212. Specifically, in some embodiments, an insulating material is formed on the substrate 100 to cover the hybrid fins 110 and 210 and to fill up the trenches 10. Next, an etching back process may be performed to remove a portion of the insulating material until the upper sidewall 112s1 of the stack of first semiconductor strips 112 and the upper sidewall 212s1 of the stack of second semiconductor strips 212 are exposed. That is, the insulating material is recessed to form the isolation structure 115. The isolation structure 115 may cover the lower sidewall 112s2 of the stack of first semiconductor strips 112 and the lower sidewall 212s2 of the stack of second semiconductor strips 212, while exposing the upper sidewall 112s1 of the stack of first semiconductor strips 112 and the upper sidewall 212s1 of the stack of second semiconductor strips 212.

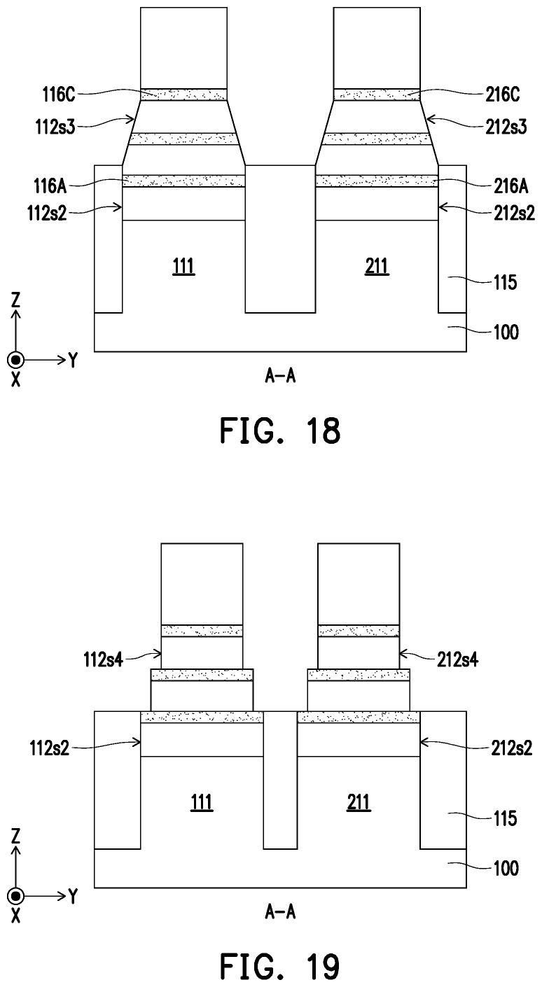

Referring to FIG. 17 and FIG. 18, a trimming process is performed to trim the upper sidewall 112s1 of the stack of first semiconductor strips 112 and the upper sidewall 212s1 of the stack of second semiconductor strips 212, thereby forming an inclined upper sidewall 112s3 of the stack of first semiconductor strips 112 and an inclined upper sidewall 212s3 of the stack of second semiconductor strips 212. In some embodiments, the etchant used in the trimming process may include NH₄OH, H₂O₂, H₂O, DIO, HF, or CH₄. In such embodiment, the upper sidewall 112s3 is tapered from the lower sidewall 112s2, so that the bottommost semiconductor nanosheets 116A has a width greater than a width of the topmost semiconductor nanosheets 116C. In addition, the upper sidewall 212s3 is also tapered from the lower sidewall 212s2, so that the bottommost semiconductor nanosheets 216A has a width greater than a width of the topmost semiconductor nanosheets 216C. After forming the inclined upper sidewalls 112s3 and 212s3, the subsequent manufacturing steps are shown in above FIGS. 6A-15B, and will not be repeated here. Although FIG. 16 to FIG. 18 only show one trimming process, the embodiments of the present disclosure are not limited thereto. In other embodiments, two or more trimming processes are performed to form various inclined sidewalls with different inclined angles.

FIG. 19 is a cross-sectional view of the semiconductor device in FIG. 18 in accordance with some alternative embodiments of the disclosure.

Depending on the etchant used in the trimming process, the exposed upper sidewalls 112s4 and 212s4 may be staircase sidewalls, as shown in FIG. 19. In some embodiments, the etchant may include NH₄OH, H₂O₂, H₂O, DIO, HF, or CH₄. In some alternative embodiments, the etchant resulting in the structure of FIG. 19 is different from the etchant resulting in the structure of FIG. 18. The number of steps on the staircase sidewalls 112s4 and 212s4 may depend on the number of trimming processes. That is, the more times the trimming process is performed, the more steps on the staircase sidewalls 112s4 and 212s4.

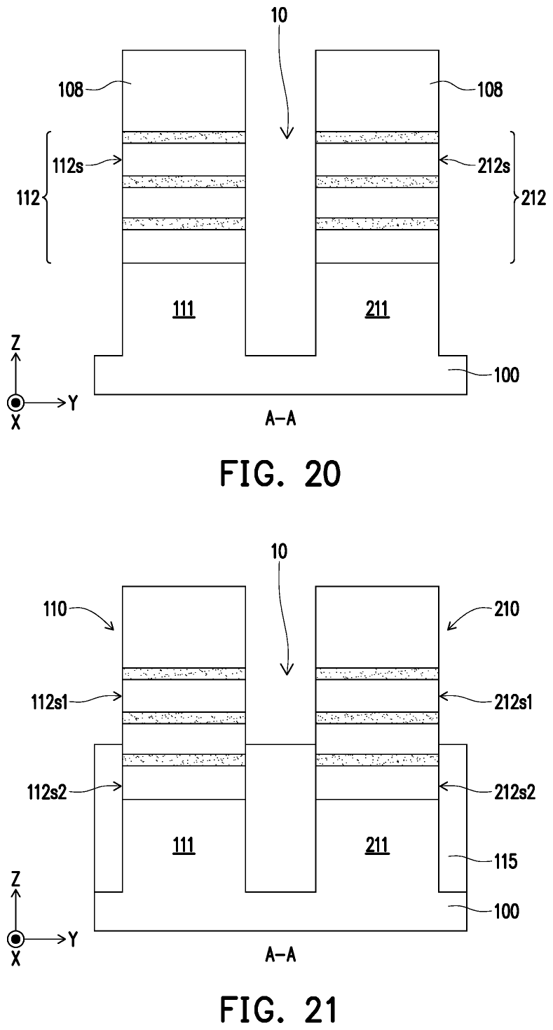

FIGS. 20, 21, 22, and 23 are corresponding fragmentary cross-sectional views of forming the semiconductor device in FIG. 1 taken along the line A-A in accordance with some embodiments of the disclosure.

Referring to FIG. 20 and FIG. 21, the steps as shown in FIG. 16 to FIG. 17 are performed to form the structure of FIG. 21. That is, the semiconductor stack 102 and the substrate 100 are patterned to form the stack of first semiconductor strips 112 on the first active region 111 and the stack of second semiconductor strips 212 on the second active region 211. Next, the isolation structure 115 is formed to laterally surround bottom portions of the stack of first semiconductor strips 112 and the stack of second semiconductor strips 212.

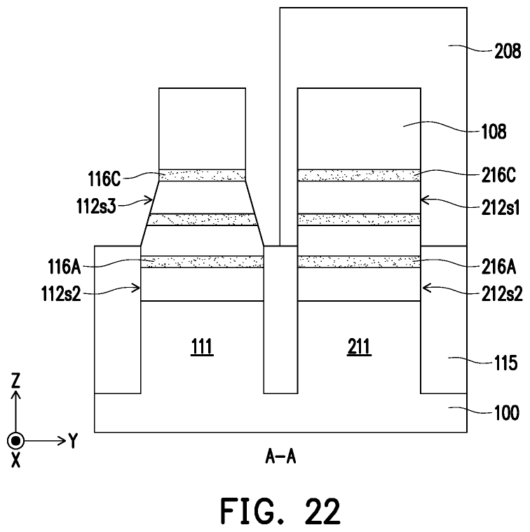

Referring to FIG. 21 and FIG. 22, a mask layer 208 is formed to cover the stack of second semiconductor strips 212 while the stack of first semiconductor strips 112 is exposed. In some embodiments, the mask layer 208 include a positive photoresist or a negative photoresist, and may be formed by any suitable method, such as spin-coating and photolithography. Afterward, a trimming process is performed with the mask layer 208 in place to trim the upper sidewall 112s1 of the stack of first semiconductor strips 112, thereby forming an inclined upper sidewall 112s3 of the stack of first semiconductor strips 112. In such embodiment, the upper sidewall 112s3 is tapered from the lower sidewall 112s2, so that the bottommost semiconductor nanosheets 116A has a width greater than a width of the topmost semiconductor nanosheets 116C. In addition, the upper sidewall 212s1 is substantially aligned with the lower sidewall 212s2, so that the bottommost semiconductor nanosheets 216A has a width substantially equal to a width of the topmost semiconductor nanosheets 216C.

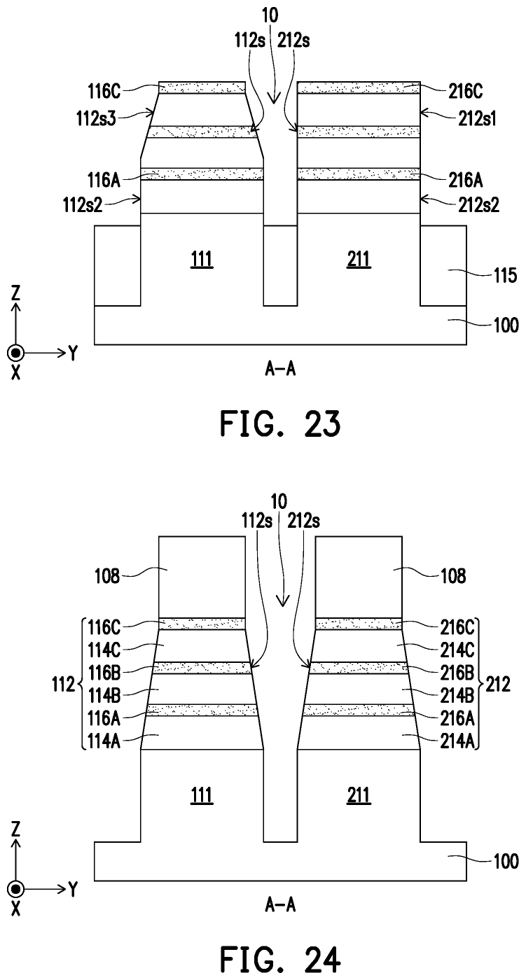

Referring to FIG. 23, the mask layer 208 and the mask pattern 108 are removed to expose the stack of first semiconductor strips 112 and the stack of second semiconductor strips 212. In some embodiments, the stack of second semiconductor strips 212 has a vertical sidewall 212s facing the inclined sidewall 112s of the stack of first semiconductor strips 112. From another point of view, the trench 10 may have a first sidewall 112s contacting the stack of first semiconductor strips 112 and a second sidewall 212s contacting the stack of second semiconductor strips 212, the first sidewall 112s is the inclined sidewall with respect to the top surface of the substrate 100, and the second sidewall 212s is substantially perpendicular to the top surface of the substrate 100. After forming the inclined upper sidewall 112s3 and the vertical upper sidewall 212s1, the subsequent manufacturing steps are shown in above FIGS. 6A-15B, and will not be repeated here.

FIGS. 24, 25, and 26 are corresponding fragmentary cross-sectional views of forming the semiconductor device in FIG. 1 taken along the line A-A in accordance with some embodiments of the disclosure. The following embodiments take nano-forksheet transistors as an example to illustrate, but the embodiments of the present disclosure are not limited thereto.

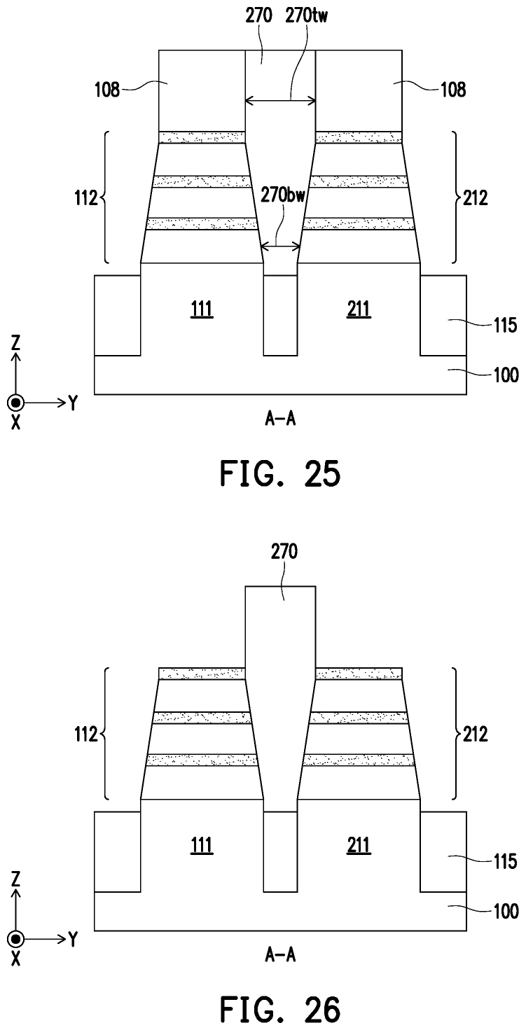

Referring to FIG. 24 and FIG. 25, the steps as shown in FIG. 3 to FIG. 4 are performed to form the structure of FIG. 24. Next, an isolation structure 115 is formed to laterally surround the active regions 111 and 211. Then, a dielectric wall 270 is formed in the trench 10 between the stack of first semiconductor strips 112 and the stack of second semiconductor strips 212. In some embodiments, the dielectric wall 270 include a dielectric material such as silicon oxide, silicon nitride, silicon oxynitride, the like, or a combination thereof, and may be formed by CVD, ALD or any suitable method. The dielectric wall 270 may be physically or electrically isolated the stack of first semiconductor strips 112 from the stack of second semiconductor strips 212. Since the trench 10 has a wider top width and a narrower bottom width, the dielectric material is easily filled in the trench 10 to form the dielectric wall 270. In some embodiments, a taperness (i.e., 270tw-270bw) between the top width 270tw of the dielectric wall 270 and the bottom width 270bw of the dielectric wall 270 is between 1 nm and 10 nm.

Referring to FIG. 26, the mask pattern 108 is removed to expose the stack of first semiconductor strips 112 and the stack of second semiconductor strips 212. The subsequent manufacturing steps are shown in above FIGS. 6A-15B, and will not be repeated here.

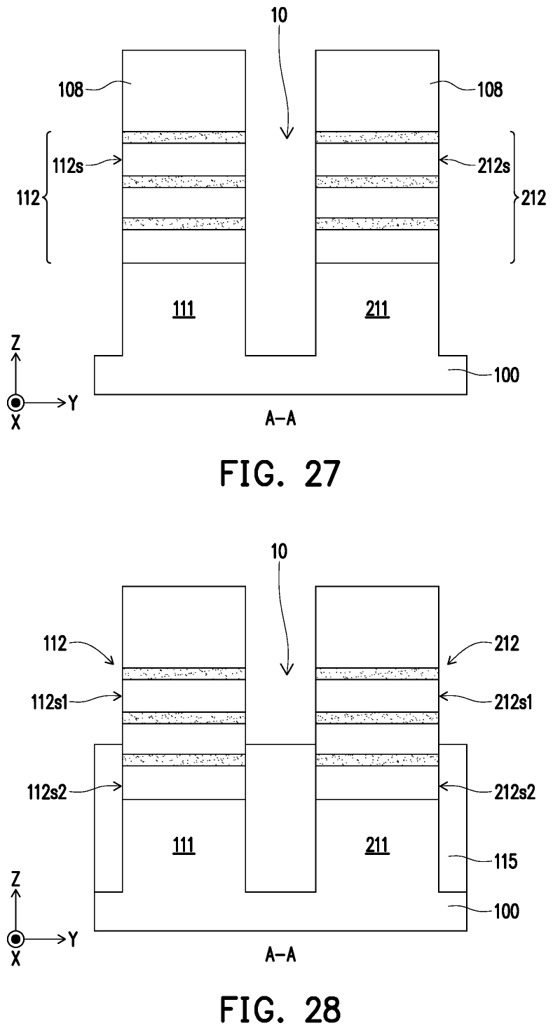

FIGS. 27, 28, 29, and 30 are corresponding fragmentary cross-sectional views of forming the semiconductor device in FIG. 1 taken along the line A-A in accordance with some embodiments of the disclosure.

Referring to FIG. 27 and FIG. 28, the steps as shown in FIG. 16 to FIG. 17 are performed to form the structure of FIG. 28.

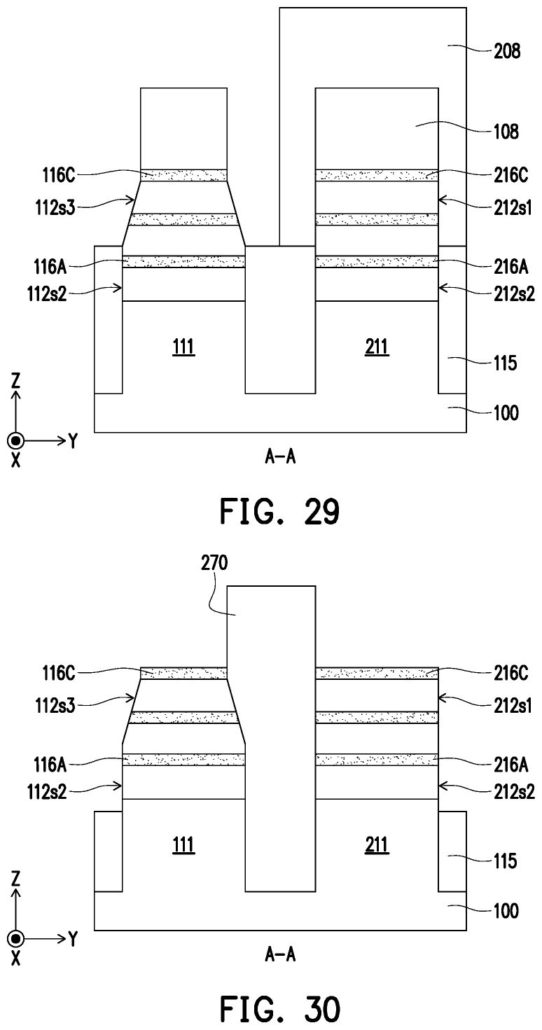

Referring to FIG. 28 and FIG. 29, a mask layer 208 is formed to cover the stack of second semiconductor strips 212 while the stack of first semiconductor strips 112 is exposed. Afterward, a trimming process is performed with the mask layer 208 in place to trim the upper sidewall 112s1 of the stack of first semiconductor strips 112, thereby forming an inclined upper sidewall 112s3 of the stack of first semiconductor strips 112. In such embodiment, the upper sidewall 112s3 is tapered from the lower sidewall 112s2, so that the bottommost semiconductor nanosheets 116A has a width greater than a width of the topmost semiconductor nanosheets 116C. In addition, the upper sidewall 212s1 is substantially aligned with the lower sidewall 212s2, so that the bottommost semiconductor nanosheets 216A has a width substantially equal to a width of the topmost semiconductor nanosheets 216C.

Referring to FIG. 30, the mask layer 208 and the mask pattern 108 are removed to expose the stack of first semiconductor strips 112 and the stack of second semiconductor strips 212. Next, the isolation structure 115 is recessed to expose the lower sidewall 112s2 of the stack of first semiconductor strips 112 and the lower sidewall 212s2 of the stack of second semiconductor strips 212. Then, a dielectric wall 270 is formed in the trench 10 between the stack of first semiconductor strips 112 and the stack of second semiconductor strips 212. After forming the inclined upper sidewall 112s3 and the vertical upper sidewall 212s1, the subsequent manufacturing steps are shown in above FIGS. 6A-15B, and will not be repeated here.

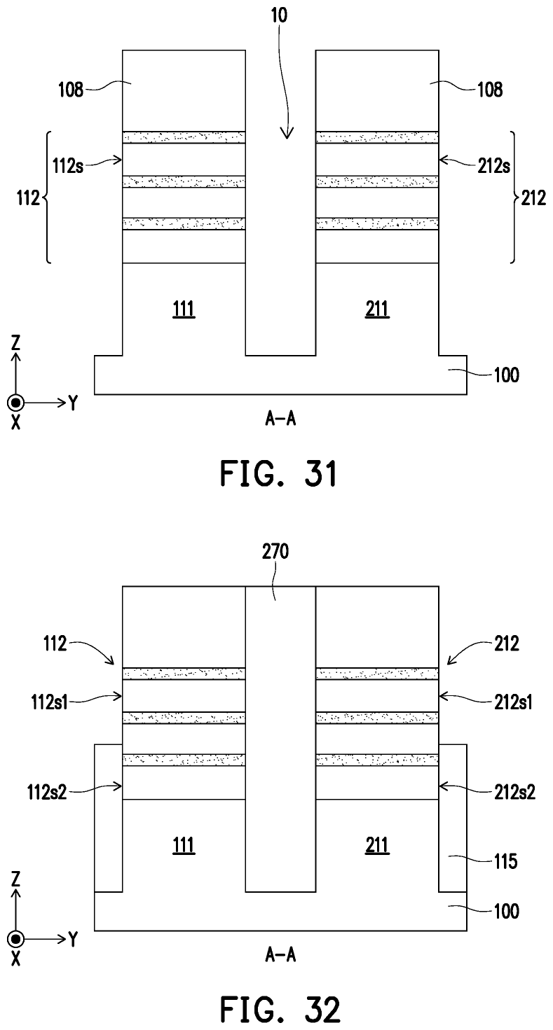

FIGS. 31, 32, 33, and 34 are corresponding fragmentary cross-sectional views of forming the semiconductor device in FIG. 1 taken along the line A-A in accordance with some embodiments of the disclosure.

Referring to FIG. 31 and FIG. 32, the steps as shown in FIG. 16 are performed to form the structure of FIG. 31. Then, a dielectric wall 270 is formed in the trench 10 between the stack of first semiconductor strips 112 and the stack of second semiconductor strips 212. Next, the isolation structure 115 is formed to laterally surround the lower sidewall 112s2 of the stack of first semiconductor strips 112, the lower sidewall 212s2 of the stack of second semiconductor strips 212, and the lower portion of the dielectric wall 270.

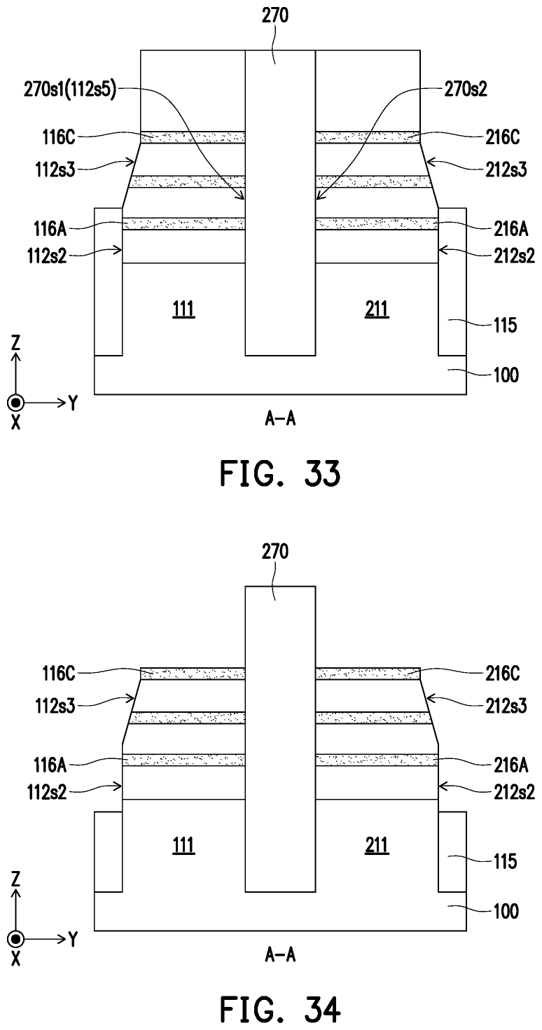

Referring to FIG. 32 and FIG. 33, a trimming process is performed to trim the upper sidewall 112s1 of the stack of first semiconductor strips 112 and the upper sidewall 212s1 of the stack of second semiconductor strips 212, thereby forming an inclined upper sidewall 112s3 of the stack of first semiconductor strips 112 and an inclined upper sidewall 212s3 of the stack of second semiconductor strips 212. In such embodiment, the upper sidewall 112s3 is tapered from the lower sidewall 112s2, so that the bottommost semiconductor nanosheets 116A has a width greater than a width of the topmost semiconductor nanosheets 116C. In addition, the upper sidewall 212s3 is also tapered from the lower sidewall 212s2, so that the bottommost semiconductor nanosheets 216A has a width greater than a width of the topmost semiconductor nanosheets 216C. As shown in FIG. 33, the dielectric wall 270 may have a first sidewall 270s1 contacting the stack of first semiconductor strips 112 and a second sidewall 270s2 contacting the stack of second semiconductor strips 212. In some embodiments, the first sidewall 270s1 and the second sidewall 270s2 are both perpendicular to the top surface of the substrate 100. That is, the dielectric wall 270 has a bottom width substantially equal to a top width thereof. From another point of view, the stack of first semiconductor strips 112 is an asymmetric structure with the inclined sidewall 112s3 and the opposite vertical sidewall 112s5.

Referring to FIG. 34, the mask pattern 108 is removed to expose the stack of first semiconductor strips 112 and the stack of second semiconductor strips 212. After forming the inclined upper sidewalls 112s3 and 212s3, the subsequent manufacturing steps are shown in above FIGS. 6A-15B, and will not be repeated here.

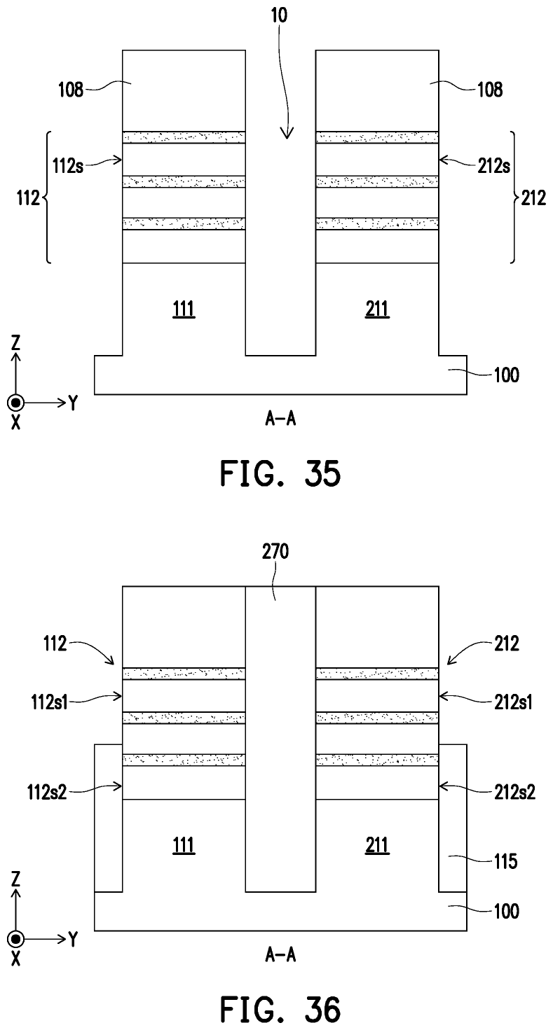

FIGS. 35, 36, 37, and 38 are corresponding fragmentary cross-sectional views of forming the semiconductor device in FIG. 1 taken along the line A-A in accordance with some embodiments of the disclosure.

Referring to FIG. 35 and FIG. 36, the steps as shown in FIG. 31 to FIG. 32 are performed to form the structure of FIG. 36.

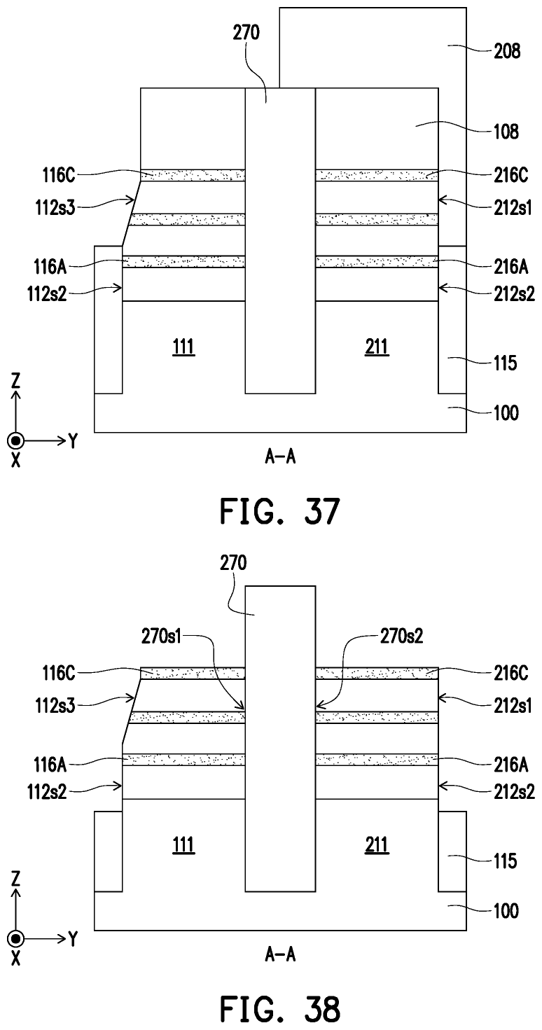

Referring to FIG. 36 and FIG. 37, a mask layer 208 is formed to cover the stack of second semiconductor strips 212 while the stack of first semiconductor strips 112 is exposed. Afterward, a trimming process is performed with the mask layer 208 in place to trim the upper sidewall 112s1 of the stack of first semiconductor strips 112, thereby forming an inclined upper sidewall 112s3 of the stack of first semiconductor strips 112. In such embodiment, the upper sidewall 112s3 is tapered from the lower sidewall 112s2, so that the bottommost semiconductor nanosheets 116A has a width greater than a width of the topmost semiconductor nanosheets 116C. In addition, the upper sidewall 212s1 is substantially aligned with the lower sidewall 212s2, so that the bottommost semiconductor nanosheets 216A has a width substantially equal to a width of the topmost semiconductor nanosheets 216C.

Referring to FIG. 37 and FIG. 38, the mask layer 208 and the mask pattern 108 are removed to expose the stack of first semiconductor strips 112 and the stack of second semiconductor strips 212. In this case, as shown in FIG. 38, the dielectric wall 270 may have a first sidewall 270s1 contacting the stack of first semiconductor strips 112 and a second sidewall 270s2 contacting the stack of second semiconductor strips 212. In some embodiments, the first sidewall 270s1 and the second sidewall 270s2 are both perpendicular to the top surface of the substrate 100. That is, the dielectric wall 270 has a bottom width substantially equal to a top width thereof. After forming the inclined upper sidewall 112s3 and the vertical upper sidewall 212s1, the subsequent manufacturing steps are shown in above FIGS. 6A-15B, and will not be repeated here.

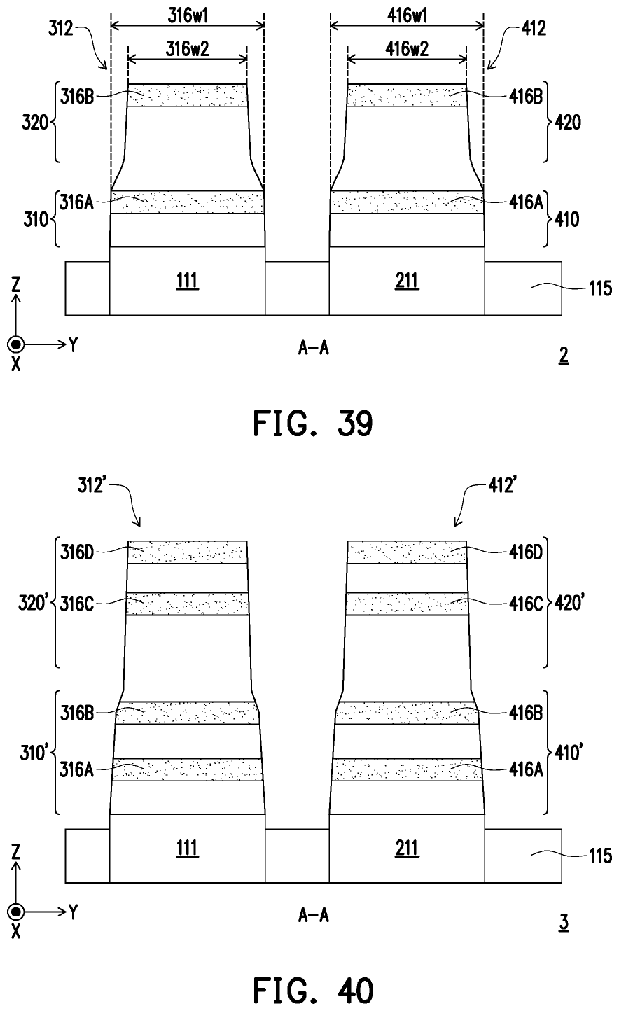

FIG. 39 is a corresponding fragmentary cross-sectional view of the semiconductor device in FIG. 1 taken along the line A-A in accordance with some embodiments of the disclosure. The following embodiments take complementary FET (CFET) as an example to illustrate, but the embodiments of the present disclosure are not limited thereto.

Referring to FIG. 39, a semiconductor device 2 may include a first active region 111, a stack of first semiconductor strips 312 on the first active region 111, a second active region 211, and a stack of second semiconductor strips 412 on the second active region 211. The stack of first semiconductor strips 312 may have semiconductor nanosheets 316A and 316B stacked along the Z direction, and the bottom semiconductor nanosheets 316A has a width greater than a width of the top semiconductor nanosheets 316B. In such embodiment, the semiconductor nanosheet 316A is referred to as the channel layer of a first transistor 310, and the semiconductor nanosheet 316B is referred to as the channel layer of a second transistor 320 different from the first transistor 310. In some embodiments, the first transistor 310 and the second transistor 320 have different conductivities. For example, the first transistor 310 may be a p-type FET, and the second transistor 320 may be a n-type FET, vice versa. In such embodiment, the semiconductor nanosheets 316A and 316B have different channel materials for different devices. As shown in FIG. 39, the second transistor 320 with the narrower channel width may be stacked on the first transistor 310 with the wider channel width. Since the bottom transistor 310 has the wider channel width, the effective channel width is increased and the channel resistance is reduced. In some embodiments, a taperness (i.e., 316w1-316w2) between the bottom semiconductor nanosheet 316A and the top semiconductor nanosheet 316B is between 1 nm and 50 nm.

In addition, the stack of second semiconductor strips 412 may have semiconductor nanosheets 416A and 416B stacked along the Z direction, and the bottom semiconductor nanosheets 416A has a width greater than a width of the top semiconductor nanosheets 416B. In such embodiment, the semiconductor nanosheet 416A is referred to as the channel layer of a first transistor 410, and the semiconductor nanosheet 416B is referred to as the channel layer of a second transistor 420 different from the first transistor 410. In some embodiments, the first transistor 410 and the second transistor 420 have different conductivities. For example, the first transistor 410 may be a p-type FET, and the second transistor 420 may be a n-type FET, vice versa. That is, the second transistor 420 with the narrower channel width may be stacked on the first transistor 410 with the wider channel width. Since the bottom transistor 410 has the wider channel width, the effective channel width is increased and the channel resistance is reduced. In some embodiments, a taperness (i.e., 416w1-416w2) between the bottom semiconductor nanosheet 416A and the top semiconductor nanosheet 416B is between 1 nm and 50 nm.

Although the transistors 310, 320, 410, and 420 illustrated in FIG. 39 only shows a single channel layer, the embodiments of the present disclosure are not limited thereto. In other embodiments, the number of channel layers may be adjusted according to the needs. As shown in FIG. 40, a semiconductor device 3 may include a first active region 111, a stack of first semiconductor strips 312′ on the first active region 111, a second active region 211, and a stack of second semiconductor strips 412′ on the second active region 211. The stack of first semiconductor strips 312′ may have semiconductor nanosheets 316A. 316B, 316C. 316D stacked along the Z direction, and the bottommost semiconductor nanosheets 316A has a width greater than a width of the topmost semiconductor nanosheets 316D. In such embodiment, a second transistor 320′ with two or more channel layers is stacked on a first transistor 310′ with two or more channel layers. In addition, the stack of second semiconductor strips 412′ may have semiconductor nanosheets 416A, 416B, 416C, and 416D stacked along the Z direction, and the bottommost semiconductor nanosheets 416A has a width greater than a width of the topmost semiconductor nanosheets 416D. In such embodiment, a second transistor 420′ with two or more channel layers is stacked on a first transistor 410′ with two or more channel layers.

According to some embodiments, a semiconductor device includes a substrate, a plurality of first semiconductor structures, a plurality of second semiconductor structures, a first source/drain (S/D) region, a second S/D region, a first gate stack, and a second gate stack. The substrate includes a first active region and a second active region extending along a first direction. The first semiconductor structures are stacked on the first active region. The second semiconductor structures are stacked on the second active region. The first S/D region abuts the first semiconductor structures. The second S/D region abuts the second semiconductor structures. The first gate stack wraps the first semiconductor structures and extends along a second direction different from the first direction. The second gate stack wraps the second semiconductor structures and extends along the second direction. A bottommost first semiconductor structure of the first semiconductor structures has a width in the second direction greater than a width of a topmost first semiconductor structure of the first semiconductor structures in the second direction.

According to some embodiments, a method of forming a semiconductor device includes: forming a semiconductor stack on a substrate, wherein the semiconductor stack comprises a plurality of first layers and a plurality of second layers stacked alternately; patterning the semiconductor stack and the substrate to form a stack of first semiconductor strips and a stack of second semiconductor strips, wherein the stack of first semiconductor strips and the stack of second semiconductor strips extend along a first direction, the stack of first semiconductor strips has a bottom width and a top width in a second direction different from the first direction, and the bottom width is greater than the top width; forming a dummy gate stack across the stack of first semiconductor strips and the stack of second semiconductor strips; removing portions of the stack of first semiconductor strips and the stack of second semiconductor strips at opposite sides of the dummy gate stack to form first source/drain (S/D) recesses and second S/D recesses exposing the substrate; and forming first S/D regions in the first S/D recesses and forming second S/D regions in the second S/D recesses.

According to some embodiments, a semiconductor device includes a substrate comprising an active region extending along a first direction; a first transistor stacked on the active region; and a second transistor stacked on the first transistor, wherein the first transistor has a channel width in the second direction greater than a channel width of the second transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprising a first active region and a second active region thereon, wherein the first and second active regions extend along a first direction;
a plurality of first semiconductor structures stacked on the first active region;
a plurality of second semiconductor structures stacked on the second active region;
a first source/drain (S/D) region abutting the plurality of first semiconductor structures;
a second S/D region abutting the plurality of second semiconductor structures;
a first gate stack wrapping the plurality of first semiconductor structures and extending along a second direction different from the first direction; and
a second gate stack wrapping the plurality of second semiconductor structures and extending along the second direction,
wherein a bottommost first semiconductor structure of the plurality of first semiconductor structures has a width in the second direction greater than a width of a topmost first semiconductor structure of the plurality of first semiconductor structures in the second direction.

2. The semiconductor device of claim 1, wherein a bottommost second semiconductor structure of the plurality of second semiconductor structures has a width in the second direction greater than a width of a topmost second semiconductor structure of the plurality of second semiconductor structures in the second direction.

3. The semiconductor device of claim 1, wherein a space between the bottommost first semiconductor structure and a bottommost second semiconductor structure of the plurality of second semiconductor structures is less than a space between the topmost first semiconductor structure and a topmost second semiconductor structure of the plurality of second semiconductor structures.

4. The semiconductor device of claim 1, wherein a bottommost second semiconductor structure of the plurality of second semiconductor structures has a sidewall substantially aligned with a sidewall of a topmost second semiconductor structure of the plurality of second semiconductor structures.

5. The semiconductor device of claim 1, wherein a trench formed between the plurality of first semiconductor structures and the plurality of second semiconductor structures, and the trench has a wider top width and a narrower bottom width.

6. The semiconductor device of claim 5, wherein the trench has a first sidewall contacting the plurality of first semiconductor structures and a second sidewall contacting the plurality of second semiconductor structures, and one of the first sidewall or the second sidewall are substantially perpendicular to a top surface of the substrate.

7. The semiconductor device of claim 1, wherein a trench formed between the plurality of first semiconductor structures and the plurality of second semiconductor structures, and the trench has a top width substantially equal to a bottom width thereof.

8. The semiconductor device of claim 1, further comprising a dielectric wall disposed in a trench between the plurality of first semiconductor structures and the plurality of second semiconductor structures.

9. The semiconductor device of claim 1, wherein the plurality of first semiconductor structures and the plurality of second semiconductor structures comprise semiconductor nanosheets, semiconductor wires, or a combination thereof.

10. A method of forming a semiconductor device, comprising:
forming a semiconductor stack on a substrate, wherein the semiconductor stack comprises a plurality of first layers and a plurality of second layers stacked alternately;
patterning the semiconductor stack and the substrate to form a stack of first semiconductor strips and a stack of second semiconductor strips, wherein the stack of first semiconductor strips and the stack of second semiconductor strips extend along a first direction, the stack of first semiconductor strips has a bottom width and a top width in a second direction different from the first direction, and the bottom width is greater than the top width;
forming a dummy gate stack across the stack of first semiconductor strips and the stack of second semiconductor strips;
removing portions of the stack of first semiconductor strips and the stack of second semiconductor strips at opposite sides of the dummy gate stack to form first source/drain (S/D) recesses and second S/D recesses exposing the substrate; and
forming first S/D regions in the first S/D recesses and forming second S/D regions in the second S/D recesses.

11. The method of claim 10, further comprising:
removing the dummy gate stack;
performing an etching process to remove the plurality of first layers and form a plurality of gaps between the plurality of the second layers;
forming a gate dielectric layer wrapping the plurality of the second layers;
forming a first gate electrode to cover the gate dielectric layer of the stack of first semiconductor strips; and
forming a second gate electrode to cover the gate dielectric layer of the stack of second semiconductor strips.

12. The method of claim 11, wherein the plurality of first layers and the plurality of second layers have different etching selectivities in the etching process.

13. The method of claim 10, further comprising forming a plurality of inner spacers between the first and second S/D regions and the plurality of first layers.

14. The method of claim 10, wherein after patterning the semiconductor stack and the substrate, the method further comprises:
forming an isolation structure to laterally surround bottom portions of the stack of first semiconductor strips and the stack of second semiconductor strips; and
performing a trimming process, so that an upper sidewall of the stack of first semiconductor strips is trimmed to form a first inclined sidewall and an upper sidewall of the stack of second semiconductor strips is trimmed to form a second inclined sidewall.

15. The method of claim 10, wherein after patterning the semiconductor stack and the substrate, the method further comprises:
forming an isolation structure to laterally surround bottom portions of the stack of first semiconductor strips and the stack of second semiconductor strips;
forming a mask layer to cover the stack of second semiconductor strips;
performing a trimming process with the mask layer in place, so that an upper sidewall of the stack of first semiconductor strips is trimmed to form a first inclined sidewall; and
removing the mask layer, so that the stack of second semiconductor strips has a vertical sidewall facing the first inclined sidewall of the stack of first semiconductor strips.

16. The method of claim 10, wherein after patterning the semiconductor stack and the substrate, the method further comprises:
forming a dielectric wall in a trench between the stack of first semiconductor strips and the stack of second semiconductor strips.

17. The method of claim 16, wherein after forming the dielectric wall, the method further comprises:
forming an isolation structure to laterally surround bottom portions of the stack of first semiconductor strips, the stack of second semiconductor strips, and the dielectric wall; and
performing a trimming process, so that an upper sidewall of the stack of first semiconductor strips is trimmed to form a first inclined sidewall and an upper sidewall of the stack of second semiconductor strips is trimmed to form a second inclined sidewall.

18. The method of claim 16, wherein after forming the dielectric wall, the method further comprises:
forming an isolation structure to laterally surround bottom portions of the stack of first semiconductor strips, the stack of second semiconductor strips, and the dielectric wall;
forming a mask layer to cover the stack of second semiconductor strips and the dielectric wall;
performing a trimming process with the mask layer in place, so that an upper sidewall of the stack of first semiconductor strips is trimmed to form a first inclined sidewall; and
removing the mask layer, so that the stack of second semiconductor strips has a vertical sidewall away from the first inclined sidewall of the stack of first semiconductor strips.

19. A semiconductor device, comprising:
a substrate comprising an active region extending along a first direction;
a first transistor stacked on the active region; and
a second transistor stacked on the first transistor, wherein the first transistor has a channel width in the second direction greater than a channel width of the second transistor.

20. The semiconductor device of claim 19, wherein the first transistor and the second transistor have different conductivities.
